(19) United States
(12) Patent Application Publication
(10) Pub. No.: US 2025/0386603 A1
(43) Pub. Date: Dec. 18, 2025

(54) PENETRATION DEPTH BASED MULTISPECTRAL PHOTODETECTION

(71) Applicant: The Regents of the University of California, Oakland, CA (US)

(72) Inventors: Oscar Vazquez Mena, Chula Vista, CA (US); Seungbae Ahn, Busan (KR); Ju Ying Shang, La Jolla, CA (US)

(21) Appl. No.: 19/242,846

(22) Filed: Jun. 18, 2025

Related U.S. Application Data
(60) Provisional application No. 63/661,484, filed on Jun. 18, 2024.

(51) Int. Cl. H10F 39/18; B82Y 20/00; H10F 39/00

(52) U.S. Cl. CPC H10F 39/1825; H10F 39/016; B82Y 20/00

(57) ABSTRACT

Devices and methods for penetration depth based multispectral photodetection are disclosed. An exemplary device includes: a plurality of light-absorbing layers configured to absorb light and generate photocarriers; a plurality of charge-collecting layers intercalated with and electrically connected to respective light-absorbing layers, each charge-collecting layer being configured to collect photocarriers generated by a corresponding electrically connected light-absorbing layer; and a plurality of electrodes electrically connected to respective charge-collecting layers at different depths within the device, wherein the device is configured such that different wavelengths of incident light penetrate to different depths within the device, enabling multispectral detection based on photocurrent responses from the plurality of charge-collecting layers measured through the respective electrodes.

### CROSS-REFERENCE TO RELATED APPLICATIONS

This application claims priority to the provisional application with Ser. No. 63/661,484, titled “DEVICE TO RECOGNIZE AND DISCRIMINATE WAVELENGTHS OF LIGHT SOURCES,” filed Jun. 18, 2024. The entire contents of the above noted provisional application are incorporated by reference as part of the disclosure of this document.

### STATEMENT REGARDING FEDERALLY SPONSORED RESEARCH OR DEVELOPMENT

This invention was made with government support under 2046176 and ECCS-1542148 both awarded by the National Science Foundation. The U.S. government has certain rights in the invention.

### TECHNICAL FIELD

The present technology relates to multispectral photodetection, and particularly to penetration depth based multispectral photodetection.

### BACKGROUND

Multispectral photodetection involves the simultaneous detection and analysis of multiple wavelengths of light across different spectral bands. This technology finds applications in diverse fields.

### SUMMARY

An aspect of the present document relates to a multispectral photodetector device. An exemplary device includes: a plurality of light-absorbing layers configured to absorb light and generate photocarriers; a plurality of charge-collecting layers intercalated with and electrically connected to respective light-absorbing layers, each charge-collecting layer being configured to collect photocarriers generated by a corresponding electrically connected light-absorbing layer; and a plurality of electrodes electrically connected to respective charge-collecting layers at different depths within the device, wherein the device is configured such that different wavelengths of incident light penetrate to different depths within the device, enabling multispectral detection based on photocurrent responses from the plurality of charge-collecting layers measured through the respective electrodes.

Another aspect of the present document relates to a method of multispectral photodetection. An exemplary method includes: providing incident light to a photodetector device comprising a plurality of light-absorbing layers intercalated with and electrically connected to respective charge-collecting layers, wherein each charge-collecting layer is connected to a respective pair of electrodes; collecting photocarriers at different charge-collecting layers configured to collect photocarriers generated by corresponding electrically connected light-absorbing layers; measuring photocurrent responses from each charge-collecting layer through the respective electrodes; and determining spectral components of the incident light based on the measured photocurrent responses, wherein different wavelengths of the incident light penetrate to different depths within the device enabling the multispectral photodetection.

A further aspect of the present document relates to a method of manufacturing a multispectral photodetector device. An exemplary method includes: providing a substrate with a plurality of electrodes that are electrically separate from each other; and forming a plurality of detection layers, each of which comprises a charge-collecting layer and a light-absorbing layer, by repeating operations including: forming a charge-collecting layer in electrical connection with a pair of electrodes; and forming a light-absorbing layer in electrical connection with the charge-collecting layer, the light-absorbing layer being configured to absorb light and generate photocarriers to be collected by the charge-collecting layer for generating a photocurrent response, wherein the device is configured such that different wavelengths of incident light penetrate to different depths within the device, enabling multispectral detection based on the photocurrent responses from the plurality of charge-collecting layers measured through the respective electrodes.

A still further aspect of the present document relates to a device for detecting wavelengths of light. An exemplary device includes: a substrate; a first set of layers comprising quantum dots, the first set of layers configured to generate photocarriers from light incident upon the device such that a photocurrent is produced within the device; a second set of layers comprising graphene, the second set of layers configured to collect the photocurrent by absorbing the photocarriers generated by the first set of layers; and electrodes in contact with respective layers of the second set of layers at different depths within the device, wherein the first set of layers and the second set of layers are arranged on the substrate in a configuration that enables wavelengths of the light to be detected based on a decay rate of the photocurrent collected by respective layers of the second set of layers.

The foregoing general description of the illustrative embodiments and the following detailed description thereof are merely exemplary aspects of the teachings of this disclosure and are not restrictive.

### BRIEF DESCRIPTION OF FIGURES

Non-limiting and non-exhaustive examples are described with reference to the following figures.

FIG. 1 illustrates an operation principle according to some embodiments of the present technology.

FIGS. 2A and 2B illustrate a device scheme and an image of a device according to some embodiments of the present technology.

FIG. 3A, 3B, 3C and 3D illustrate fabrication processes according to some embodiments of the present technology.

FIG. 4 shows a schematic of a single-bandgap device and various parameters thereof.

FIG. 5 shows current/voltage (I/V) curves in an exemplary single-bangdap device as illustrated in FIG. 4.

FIGS. 6A and 6B show UV/Vis absorption spectra and transmission electron microscopy (TEM) images of QDs of an exemplary single-bandgap device as illustrated in FIG. 4.

FIG. 7 shows absorption through an entire stack as a function of wavelengths for an exemplary single-bandgap device as illustrated in FIG. 4.

FIG. 8 shows photocurrent depth coefficient fittings for an exemplary single-bandgap device as illustrated in FIG. 4.

FIG. 9 shows time responses for an exemplary single-bandgap device as illustrated in FIG. 4.

FIG. 10 shows time response fittings for an exemplary single-bandgap device as illustrated in FIG. 4.

FIG. 11 shows a schematic of a multi-bandgap device and various parameters thereof.

FIGS. 12A and 12B show UV/Vis absorption spectra and transmission electron microscopy (TEM) images of QDs of an exemplary multi-bandgap device as illustrated in FIG. 11.

FIG. 13 shows current/voltage (I/V) curves in an exemplary single-bandgap device as illustrated in FIG. 11.

FIG. 14 shows absorption through an entire stack as a function of wavelengths for an exemplary multi-bandgap device as illustrated in FIG. 11.

FIG. 15 shows photocurrent depth coefficient fittings for an exemplary multi-bandgap device as illustrated in FIG. 11.

FIG. 16 shows time responses for an exemplary multi-bandgap device as illustrated in FIG. 11.

FIG. 17 shows time response fittings for an exemplary multi-bandgap device as illustrated in FIG. 11.

FIG. 18 shows an exemplary multispectral photodetection device according to some embodiments of the present technology.

FIG. 19 shows the flowchart of a process of multispectral photodetection according to some embodiments of the present technology.

FIG. 20 shows the flowchart of a process of manufacturing a multispectral photodetection device according to some embodiments of the present technology.

### DETAILED DESCRIPTION

The following description sets forth exemplary aspects of the present disclosure. It should be recognized, however, that such description is not intended as a limitation on the scope of the present disclosure. Rather, the description also encompasses combinations and modifications to those exemplary aspects described herein. In addition, section headings are used in the present document only to improve readability and do not limit scope of the disclosed embodiments and techniques in each section to only that section.

### 0. Initial Remarks

Hybrid photodetectors with 2D materials and quantum dots (QDs) offer opportunities for spectral detection given their high mobilities and spectral tunability, respectively. The present technology provides an architecture of alternating light-absorbing layers (e.g., layers with PbS QDs) with charge-collecting layers (e.g., graphene monolayers) positioned at different depths and with independent contacts. This geometry enables the probing of a photocurrent depth profile and therefore of different spectral bands. An exemplary implementation includes devices with up to 5 graphene layers and 5 QD layers intercalated, using only one type of QDs (Single-Bandgap devices) with an exciton absorption peak at 920 nm. Another exemplary implementation includes devices with different types of QDs (Multi-Bandgap devices) with exciton peaks at 850, 1190 and 1350 nm. Since the absorption depth and photoresponse is wavelength dependent, each charge-collecting layer (e.g., each graphene layer) has a different spectral response, which provides a path for spectral analysis. In exemplary implementations, it has been observed that top graphene layers have stronger response than deeper graphene layers, especially for short wavelengths. In exemplary implementations of multi-bandgap devices, it has been observed a negative photoresponse coefficient for longer wavelengths, showing stronger response for deeper layers than for top layers. This intercalated architecture can be used for compact multispectral photodetection without any diffractive or beam splitting component.

### 1. Introduction

The development of compact and broadband photodetectors with spectral analysis capabilities is beneficial for material composition and object identification analysis in applications such as remote and point-of-care health care, water and environmental quality monitoring, gas detection, counterfeit detection, food quality inspection, and autonomous transportation, among others. Building a network of such sensors able to supply information continuously is also beneficial to collect large data sets for machine learning algorithms for those same applications. Furthermore, incorporating multispectral sensor networks into mobile personal devices and autonomous vehicles can lead to novel capabilities in personal health-care and safer transport. The implementation of such networks of sensors requires low-cost, compact, and light weight multispectral light detection technologies. For visible and NIR wavelengths, Bayer filters, stacked p-n junctions, and lenslets arrays have been integrated into CMOS detectors to enable compact architectures. However, these devices are usually limited to Si absorption and cannot operate beyond the NIR. Going beyond 1000 nm, most conventional multispectral technologies require dispersive optics such as beam splitters, arrays, or interferometers with large footprints. Perovskites have also used in stacked configurations but limited to Vis-NIR range. For MWIR range, the use of epitaxial films like HgCdTe significantly increases the costs compared to Si or Ge detectors used in the Vis-NIR range. An alternative route are nanomaterials such as 2-D materials and quantum dots. With novel optoelectronic properties and capabilities in addition to their low temperature processing. For instance, two-band infrared photodetectors have been implemented using HgTe stacked colloidal quantum dot photodiodes. Black phosphorous has also been used as mid-infrared spectrometer using bias-dependent spectral tuning and machine learning. QDs patterned in a lateral architecture have allowed for a three channel multispectrometer reaching the MWIR range with HgTe QDs on a ROIC platform. The present technology provides an architecture for compact and broadband multispectral photodetection based on light absorbing layers (e.g., PbS quantum dot (QD) films) intercalated with charge-collecting layers (e.g., graphene (Gr) charge collectors) with independent electrodes to detect different spectral bands.

The hybrid system (e.g., graphene and PbS quantum dots) works efficiently as a photoconductive detector both in single junction and intercalated geometries. For instance with reference to a hybrid system including graphene and PbS quantum dots, the quantum dot layers absorb photocarriers and generate electron-hole pairs that are transferred to graphene. Graphene monolayers serve as independent charge collectors to collect photocarriers generated in adjacent, top and bottom, QD layers. The present technology uses intercalated devices with independent electrical contacts to each graphene layer at different depths, allowing to probe light penetration through the QD films and giving different spectral responses for each Gr layer. The present technology obviates any beam splitting, interferometers, filtering, or diffractive components with simultaneous recording of different graphene layers with their respective spectral bands.

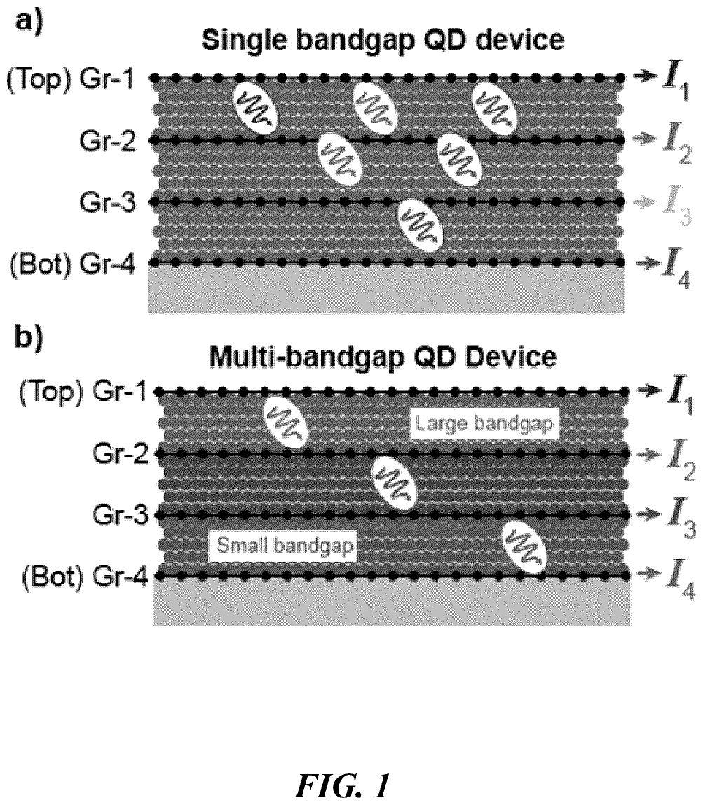

FIG. 1 illustrates an operation principle according to some embodiments of the present technology. Intercalated devices based on sequential stacking of QDs and graphene with independent electrodes to measure the current through each individual graphene monolayer (I₁ through I₄). QDs act as light absorbers and photocarrier generators. Graphene monolayers serve as independent charge collectors to collect photocarriers generated in adjacent, top and bottom, QD layers.

Panel (a) of FIG. 1 shows a single-bandgap device that contains only one size of PbS QDs. Due to the difference in absorption depth for different wavelengths, each graphene has a different spectral response. Short wavelengths with short penetration depths are absorbed mainly at the top layers while long wavelengths with deeper penetration depths are detected through the entire stack at top and bottom layers.

Panel (b) of FIG. 1 shows a multi-bandgap device that integrates different sizes of QDs with decreasing bandgaps from top to bottom. This enables to expand the spectral range of operation and tune the light absorption profile with short wavelengths absorbed at the top layers and longer wavelengths absorbed at the bottom layers. Furthermore, in the multi-bandgap devices, we obtain a negative photoresponse coefficient behavior for long wavelengths, i.e. stronger photoresponse at deeper levels. This can facilitate wavelength identification and spectral analysis in the infrared region without any dispersive or interferometer components.

### 2. Device Fabrication

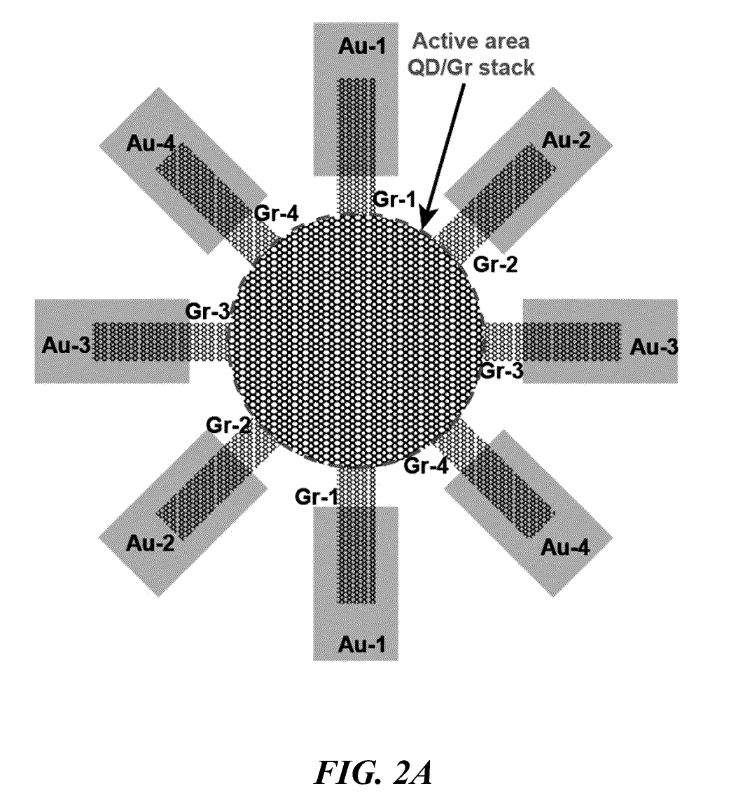

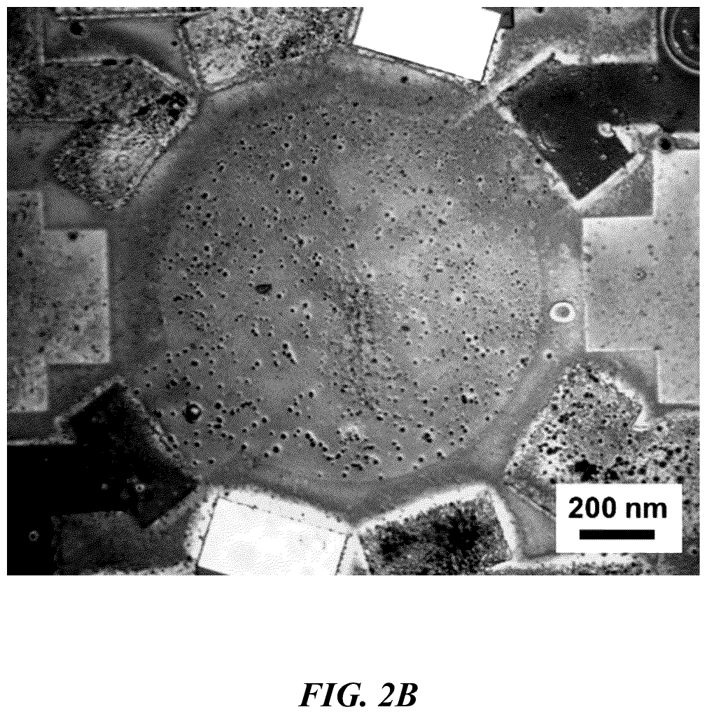

The fabrication of the devices is challenging as it needs not only the sequential deposition of graphene layers and quantum dots to produce intercalated devices, but also implementing individual contacts for each graphene layer. In some exemplary implementations, to fabricate a device disclosed herein, graphene monolayers grown by chemical vapor deposition on copper obtained from a commercial supplier (Graphenea, Spain) are used. The graphene transfers are based on wet transfer by dissolving the copper with ammonium persulfate and using PMMA as supportive layer on top of graphene, followed by the removal of the PMMA in acetone and isopropanol. The colloidal PbS QDs are synthesized using lead oxide (PbO) and bis(trimethylsilyl) sulfide as PbS precursors to obtain a solution of oleic acid functionalized QDs dissolved in toluene as described elsewhere. The PbS QD layers are prepared by spin coating of the QDs in toluene solution, followed by a ligand exchange to replace the long oleic acid chains by tetrabutylammonium iodide (TBAI) to facilitate charge transport from QD to QD. The schematic geometry of the devices from the top view is shown in FIG. 2A, showing a radial array of electrodes (or referred to as electrical contacts, or contacts for brevity). A pair of opposite electrodes serve as source and drain contacts to apply a voltage and collect the current from a corresponding graphene layer electrically connected to the pair of electrodes. The graphene layers are patterned in a circular geometry with two side arms (or referred to as connecting arms) connected to their corresponding contacts. FIG. 2A shows an array of gold electrodes electrically contacting different graphene layers at different depths in an intercalated Gr/PbS QD stacked film. A fabricated device observed under the optical microscope is shown in FIG. 2B, illustrating the gold electrodes in a radial arrangement with a central circular shaped area with the intercalated graphene and QD layers. The active area of this exemplary device is the central circular section with a 1 mm diameter, composed of intercalated graphene and PbS QD layers at different depths, each graphene layer with its own electrical contacts.

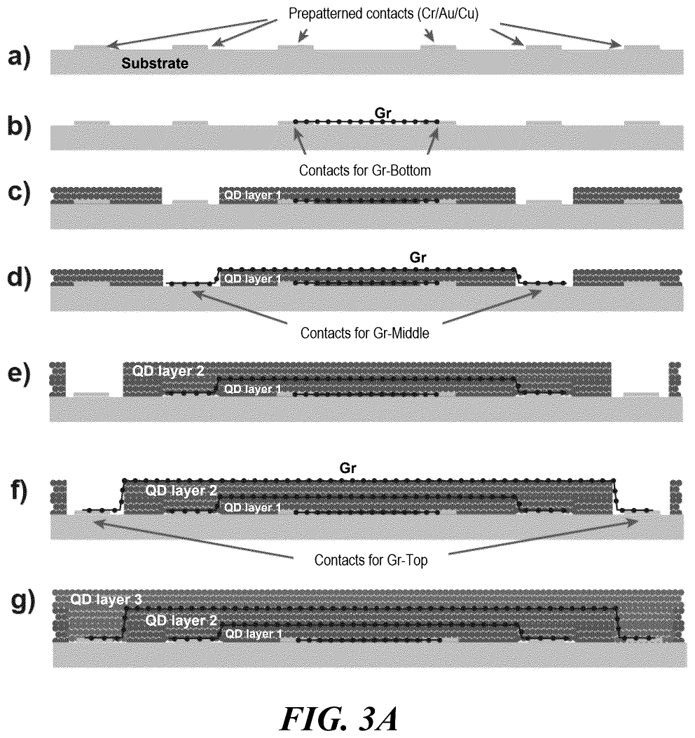

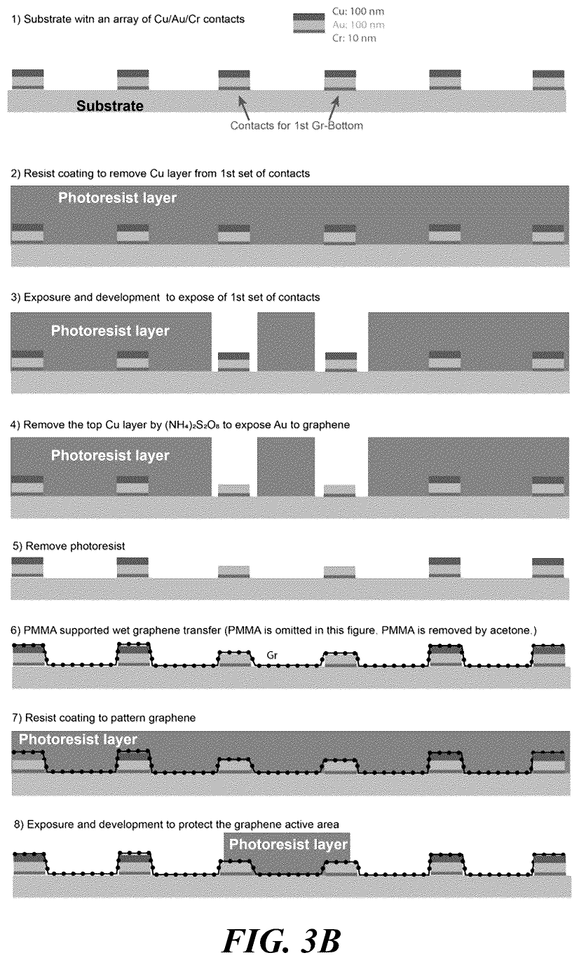

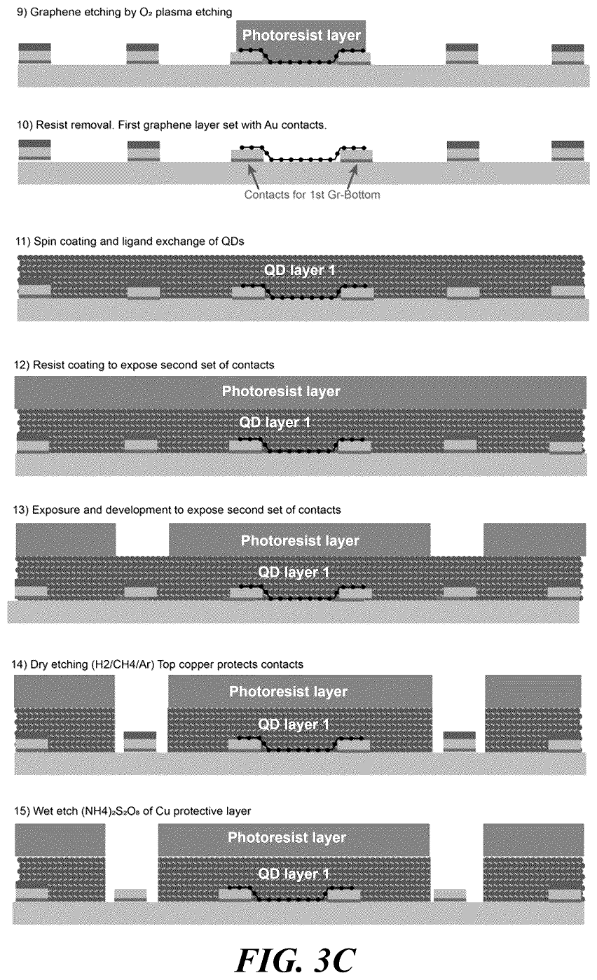

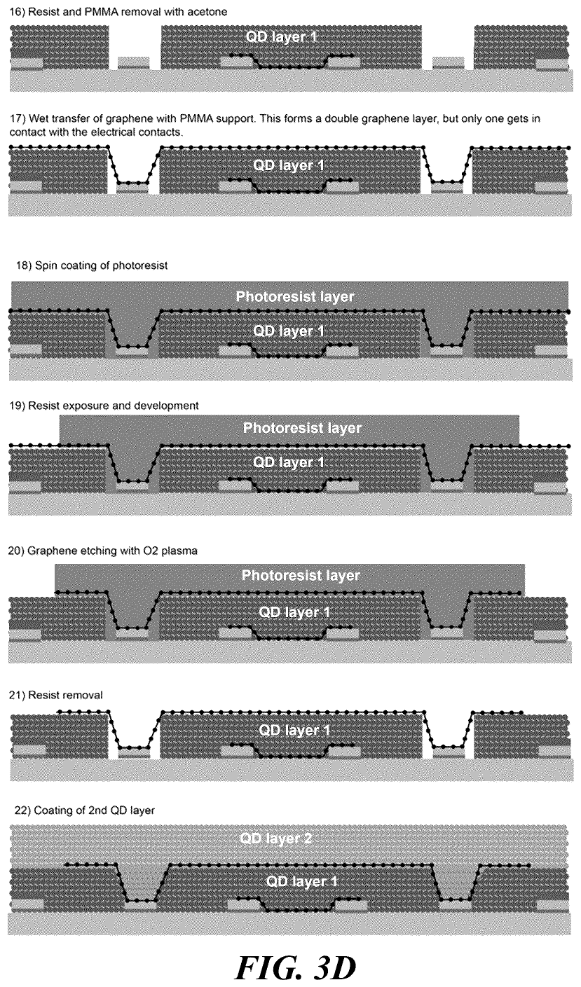

An overview of the fabrication process flow is illustrated in FIG. 3A from a side view perspective. FIG. 3A shows a process for 3 graphene and 3 QD layers, but this sequence is valid for any number of layers. The devices are built on a Si wafer (e.g., with a thickness of approximately 500 micrometer) with a silicon oxide (e.g., with a thickness of approximately 300 nm) on top. The wafers have an array of pre-patterned electrodes (or referred to as contacts or electrical contacts) made by lithography and lift-off as shown in panel (a) of FIG. 3A with the pattern shown in FIGS. 2A and 2B. The contact includes an adhesive layer (e.g., approximately 10 nm of chromium), followed by a conductive layer (e.g., approximately 100 nm of gold), and a protective layer (e.g., approximately 100 nm of copper) deposited on top (Cr/Au/Cu), as formed during PbS quantum dot (QD) etching.

The fabrication of the intercalated devices starts with the PMMA-supported wet transfer of the first graphene layer which corresponds to the first or “bottom” graphene layer as illustrated in FIG. 3A. After transfer, this graphene layer is patterned by lithography and O₂ plasma dry etching (panel (b) of FIG. 3A), defining a circular structure in the middle of the contact array, with two short channels (or referred to as side arms or connecting arms) to connect to a first set of electrodes.

After the first layer of graphene is patterned, the first layer of QDs (QD layer 1) is deposited. This is done by spin coating of QDs followed by TBAI ligand exchange. Then, before transferring a second graphene layer, the first layer of QDs is patterned by lithography and H₂/CH₄/Ar plasma dry etching to expose the second set of Au contacts (panel (c) of FIG. 3A). The goal of the patterning is to expose the contacts for the next graphene monolayer. During this etching process, the 100 nm thick copper protective layer helps to protect the gold contacts from the etching plasma. After the etching process, and before removing the patterned resist, an ammonium persulfate solution is used to remove the copper protective layer, leaving a second set of Au/Cr contacts exposed.

Then, a second graphene layer (the “middle” graphene layer as illustrated in FIG. 3A) is transferred by wet transfer (panel (d) of FIG. 3A) following the same procedure as the first or “bottom” graphene layer. This layer sits on top of the first layer of QDs, but it gets in electrical contact with the second set of Au/Cr electrical contacts. This layer is again patterned forming a circular pattern and two channels to the second set of contacts.

Then, a second layer of QDs (QD layer 2) is deposited by spin coating followed by ligand exchange. This second layer is also patterned by lithography and H₂/CH₄/Ar plasma etching, removing the QDs from a third set of contacts (panel (e) of FIG. 3A), exposing the contacts for the next graphene layer. The copper protective layer is then also removed by ammonium persulfate.

Finally, a third graphene layer (the “top” graphene layer as illustrated in FIG. 3A) is transferred and patterned (panel (f) of FIG. 3A), followed by the spin coating of a third layer of QDs (QD layer 3) which may not need further patterning (panel (g) of FIG. 3A). The sequence of steps shown in panels (d) and (e) can be repeated to build the intercalated stack with varying types of QDs.

This procedure can be performed or repeated several times to add more QD and graphene layers as desired. The total number of pre-patterned electrodes can also be adapted as needed. This general procedure can be used to fabricate devices with single or multiple bandgap quantum dots. In order to control the thickness of each QD layer, it is important to calibrate the thickness for each spin coating step. Each QD layer requires multiple spin coating steps since a single spin coating layer results in thickness of approximately 10-30 nm depending on the QD size and solution concentration. For example, for QDs with a bandgap of 1.26 eV (wavelength λ of approximately 1000 nm), each spin coating step results in an approximately 15 nm thick layer of QDs. Therefore, to obtain a film of 300 nm, the process includes spin coating a total of 20 times (layers). The circular active area has a diameter of approximately 1 mm. After fabrication, the device is characterized with a 2400 Keithley sourcemeter and a Xe lamp with a monochromator.

FIG. 3B, 3C, 3D show a more detailed and extended process flow according to some embodiments of the present technology. The detailed fabrication process includes the following steps (that are depicted across FIGS. 3B, 3C and 3D):

Step 1) Substrate with an array of Cu/Au/Cr contacts: Initial substrate preparation with pre-patterned electrode array including, from top to bottom as illustrated in FIG. 3B, a copper protective layer (e.g., 100 nm thick), a gold conductive layer (e.g., 100 nm thick), and a chromium adhesive layer (e.g., 10 nm thick) on a substrate including a silicon wafer. The electrode array may have a same or similar radial configuration as shown in FIGS. 2A and 2B.

Step 2) Resist coating to remove Cu layer from 1st set of contacts: Application of a photoresist layer across the entire substrate surface.

Step 3) Exposure and development to expose 1st set of contacts: Photolithography patterning to selectively expose areas above the first electrode set (or referred to as a first pair of electrodes).

Step 4) Remove the top Cu layer by (NH₄)₂S₂O₈ to expose Au to graphene: Wet etching using ammonium persulfate to remove the copper protective layer from exposed contact areas.

Step 5) Remove photoresist: A cleaning step to remove the remaining photoresist layer, leaving the first electrode set exposed.

Step 6) PMMA supported wet graphene transfer: Transfer of a first graphene layer (or “bottom” graphene layer) using a PMMA support layer onto the substrate surface.

Step 7) Resist coating to pattern graphene: Application of a photoresist layer over the transferred graphene.

Step 8) Exposure and development to protect the graphene active area: Photolithography to define and protect the circular graphene active region.

Step 9) Graphene etching by O₂ plasma etching: Plasma etching to remove unprotected graphene, defining a circular structure with connecting arms.

Step 10) Resist removal. A first graphene layer set with Au contacts: Cleaning to complete first graphene layer patterning with electrical connections established.

Step 11) Spin coating and ligand exchange of QDs: Deposition of a first quantum dot layer (e.g., QD layer 1) by spin coating followed by TBAI ligand exchange process.

Step 12) Resist coating to expose second set of contacts: Application of photoresist to prepare for quantum dot layer patterning.

Step 13) Exposure and development to expose second set of contacts: Photolithography to define areas for quantum dot removal.

Step 14) Dry etching (H₂/CH₄/Ar) Top copper protects contacts: Plasma etching to remove portions of the first quantum dot layer (QD layer 1) while the copper layer protects underlying contacts.

Step 15) Wet etch (NH₄)₂S₂O₈ of Cu protective layer: Removal of the copper protective layer to expose a second electrode set (or pair).

Step 16) Resist and PMMA removal with acetone: Cleaning step to remove photoresist and prepare for the next graphene transfer.

Step 17) Wet transfer of graphene with PMMA support: Transfer of second graphene layer, forming a double-layer configuration with each graphene layer being in contact with a pair of contacts (or electrodes).

Step 18) Spin coating of photoresist: Application of a photoresist layer for second graphene patterning.

Step 19) Resist exposure and development: Photolithography to define a second graphene active area.

Step 20) Graphene etching with O₂ plasma: Plasma etching to pattern a second graphene layer.

Step 21) Resist removal: Cleaning to complete the second graphene layer with established electrical connections.

Step 22) Coating of 2nd QD layer: Deposition of a second quantum dot layer (QD layer 2) by spin coating and ligand exchange.

FIGS. 3B, 3C and 3D illustrate an exemplary process for fabrication of two detection layers (each comprising a graphene layer and quantum dot layer pair). The sequence represents a repeatable cycle that can be continued to add additional detection layers as needed for the specific device requirements. Each repetition of this cycle adds one more detection layer with independent electrical contacts at increasing depths within the device. Step 1) regarding substrate preparation in FIG. 3B generally corresponds to panel (a) of FIG. 3A, steps 2)-10) regarding the preparation of the first or “bottom” graphene layer in FIGS. 3B-3C generally corresponds to panel (b) of FIG. 3A, steps 11-16 regarding the preparation of the first QD layer (QD layer 1) in FIGS. 3C-3D generally corresponds to panel (c) of FIG. 3A, steps 17-21 regarding the preparation of the second graphene layer in FIG. 3D generally corresponds to panel (d) of FIG. 3A, step 22 regarding the preparation of the second QD layer (QD layer 2) in FIGS. 3B, 3C and 3D generally corresponds to panel (e) of FIG. 3A. Panels (f) and (g) of FIG. 3A represent continuation of the intercalated layer sequence.

In some embodiments, the fabrication process (e.g., either one as illustrated in FIG. 3A or FIGS. 3B-3D) may include quantum dot synthesis and quantum dot deposition. An exemplary process for PbS quantum dot synthesis is as follows: 940 mg of lead oxide (PbO) is dissolved in 25 ml of 1-octadecene (ODE) with different amounts of oleic acid from 3.5 ml to 35 ml to achieve various extinction peak of absorption spectrum from 850 nm to 1350 nm. Then, the solution is degassed under vacuum at 90oC for two hours to be perfectly dissolved. The sulfur precursor (420 microliter of bis(trimethylsilyl) sulfide in 12.8 ml of ODE) is injected in the solution when the color of solution become clear. After that, the solution is allowed to react for 30 seconds and then cool down by placing the flask in water. The color of the solution becomes dark brown. Next, the PbS QDs is separated from the raw solution by centrifugation, followed by cleaning with toluene and acetone with three times to obtain high purity QDs. After the cleaning process, PbS QDs is dissolved in toluene to disperse, and then filtered with a 0.25 um pore size filter.

An exemplary process for quantum dot deposition is as follows: PbS QDs film is deposited using spin-coating under ambient atmosphere. For each PbS QDs layer, the QDs solution (30 mg/ml in toluene) is spin-casted at 2500 rpm for 30 s, then a solid-state ligand exchange is performed by flooding the surface with 0.03 M TBAI in methanol for 30 s before spinning dry at 2500 rpm. For the bottom Gr/QD system, QDs film is formed layer-by-layer.

In some embodiments, spectral characterization is performed as follows: The spectral response of intercalated graphene and quantum dots multispectral photodetectors is measured using a source meter (Keithley 2400) under a Xe lamp and filters (66485-500HX-R1, USFW-100, Newport) equipped with a monochromator (CS260-RG-3-FH-D, Newport). The beam size of light (approximately 2 mm by 4 mm) is enough to cover the channel of the sample. Then, the spectral response of multispectral photodetectors is measured with 10-nm step for 5 seconds to obtain a response from illuminated wavelength.

### 3. Optoelectronic Characterization

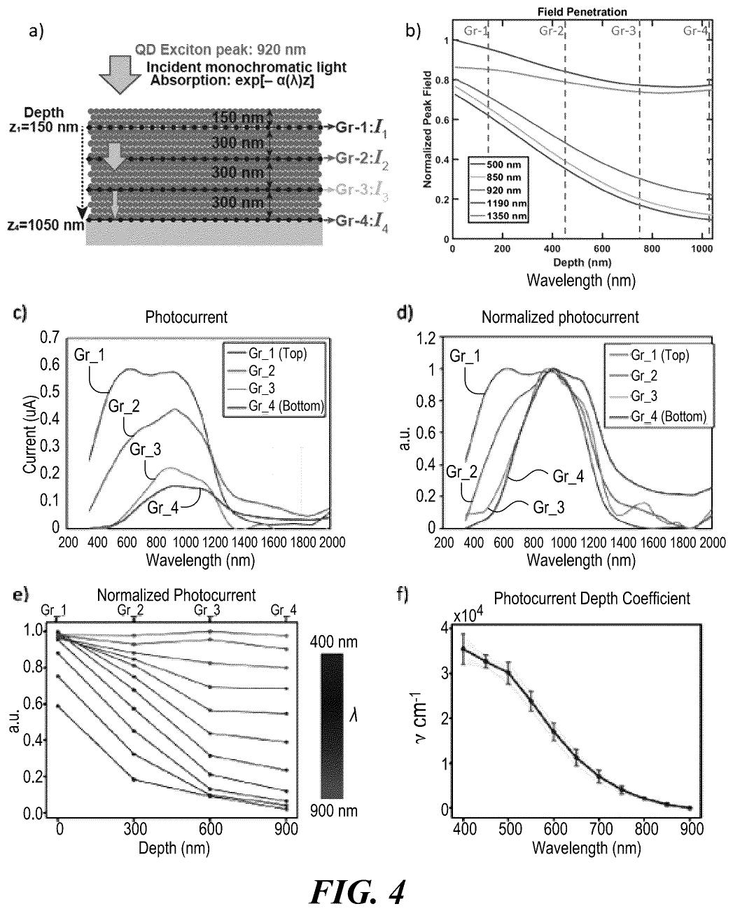

Panel (a) of FIG. 4 shows a schematic description of the single-bandgap QD device using only one type of QDs. The device includes four layers of PbS QDs intercalated with four graphene charge collectors. The top QD layer is only 150 nm thick and the three subsequent layers are 300 nm thick and therefore located at depths of z=150, 450, 750 and 1050 nm, respectively. Each graphene layer, labelled as Gr-1 to Gr-4 from top to bottom, has its own set of contacts as shown in panel (a) of FIG. 4. The thickness of 150 nm for the top QD layer and 300 nm for the rest of the QD layers is chosen to ensure that photocarriers always have a graphene layer at a distance of 150 nm, which is below the typical diffusion length of PbS QDs reported by others, ensuring that photocarriers can reach the graphene layers for effective charge collection. The resistance for each graphene was measured with a 2401 Keithley applying a voltage of 40 mV giving R=11.1, 7.2, 6.1, and 11.4 kΩ for Gr-1 to Gr-4, respectively.

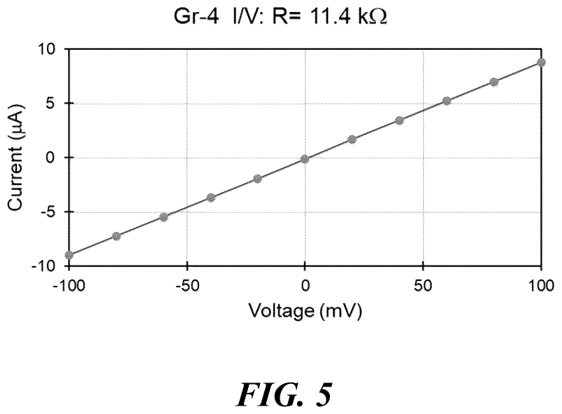

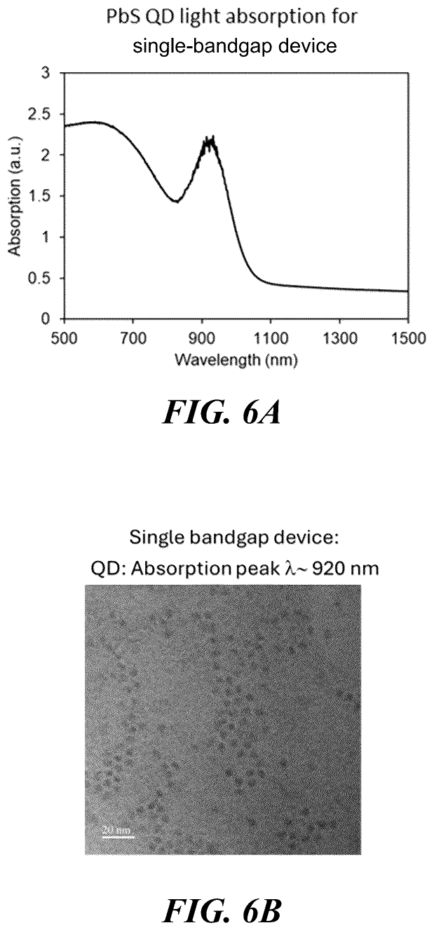

FIGS. 5 shows current/voltage (I/V) curves in the exemplary single-bangdap device as illustrated in FIG. 4. The resistance increases significantly since the current has to go across the 300 nm thick QD film. The I/V curve for Gr-4 is shown in FIG. 5. The optoelectronic measurements are carried with light incident from top with a monochromator. As the light penetrates, it is absorbed following the Beer-Lambert equation exp(−α(λ)/z), where α is the absorption coefficient that typically decreases as the wavelength λ increases. As reported in previous works, the effect of graphene on the light absorption is negligible compared to the PbS QD light absorption. FIG. 6A shows a UV/Vis absorption spectrum for PbS QD for an exemplary single-bandgap device as illustrated in FIG. 4, exhibiting an exciton resonance peak near λ˜920 nm. FIG. 6B shows transmission electron microscopy (TEM) images of the single-bandgap QDs used for an exemplary single-bandgap device as illustrated in FIG. 6A.

Finite element method simulations (CST Studio, Simulia, Dassault Systems) simulations of the light penetration (normalized field intensity vs. depth) are shown in panel (b) of FIG. 4 for λ=500 nm, 850 nm, 920 nm, 1190 nm, and 1350 nm, with the vertical dashed lines corresponding to the positions of the graphene collecting layers (Gr-1 to Gr-4). The simulations show the expected behavior of deeper penetration for longer wavelengths. In particular, λ˜500 nm, 850 nm, and 920 nm show a much shorter penetration probably due to the strong absorption as they are below or equal to the absorption threshold of the PbS QDs at λ˜1000 nm, whereas λ˜1190 nm and 1350 nm light wavelengths show mush weaker absorption.

The experimental measured photocurrent for each graphene layer under a bias voltage of 100 mV as a function of wavelength is shown in panel (c) of FIG. 4. The top graphene (Gr-1) has clearly the largest photocurrent since it experiences the largest photon flux, which leads to higher photocarrier generation and higher photocurrent. The photocurrent then decreases for deeper graphene layers as the light intensity decreases for deeper regions. However, it can also be observed that the top graphene layer (Gr-1) covers a broader spectral photoresponse compared to the bottom layer (Gr-4). Gr-1 also has its maximum photocurrent at a shorter wavelength of λ˜600 nm, while Gr-4 has its maximum photocurrent at λ˜900 nm. A slight increase in photoresponse for all monolayers is observed near λ˜2000 nm which may be due to midgap states and surface defects induced at Gr/QD interface.

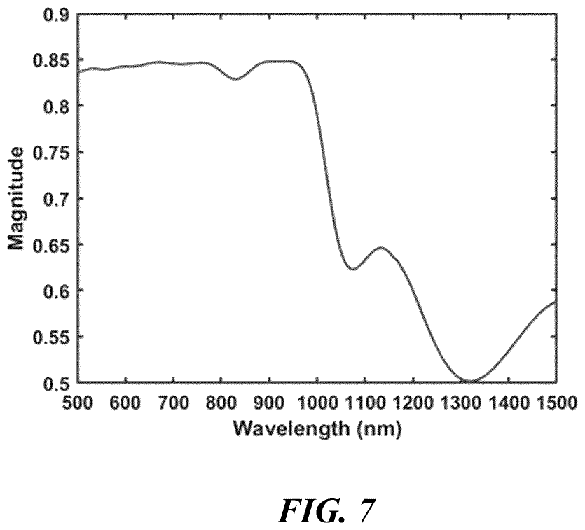

In order to compare the spectral responses, a min-max normalization for each graphene layer, as plotted in panel (d) of FIG. 4. Gr-1 has a normalized response above >0.6 (dashed reference line in panel (d) of FIG. 4) in a broad range of Δλ_{Gr-1}˜400-1150 nm, while Gr-4 has a response above 0.6 in a narrower and red-shifted range of Δλ_{Gr-4}˜700-1300 nm. In the short wavelength range of λ˜400-900 nm, the normalized photocurrent of the top graphene Gr-1 is clearly higher than the rest of the layers, followed by Gr-2 and then by very similar responses from Gr-3 and Gr-4. This behavior may be due to absorption depths increase with increasing wavelength for semiconductors. As the top QD layers absorb the short wavelength photons, the bottom QD layers encounter much reduced number of photons, which results in less photogenerated carriers and less photocurrent collected by the bottom graphene layers. When longer wavelength photons are incident on the single bandgap device, they are not all absorbed by the top QD layers, due to the photons' lower energy which leads to less scattering and absorption. The longer wavelength photons penetrate deeper and are encountered at a higher number by the bottom layers, which results in higher photocurrents. FIG. 7 shows absorption through the entire stack as a function of wavelengths for the exemplary single-bandgap device in FIG. 4, obtained by finite element method (FEM) simulation of light absorption. FIG. 7 shows significant absorption up to λ˜1300 nm, in agreement with the normalized photocurrent showing significant response for all layers up to λ˜1300 nm as well in panel (d) of FIG. 4.

To study the decay in photoresponse through the graphene layers, the normalized photoresponses as a function of depth (penetration depth) for different wavelengths are shown in panel (e) of FIG. 4. The discreet values in depth of z=150, 450, 750, and 1050 nm correspond to the positions of the graphene layers in panel (a) of FIG. 4. This plot shows how short wavelengths from 400 to 600 nm show rapid decays close to an exponential decay that resembles the behavior for light absorption from the Beer-Lambert law. Panel (e) of FIG. 4 shows a normalized photocurrent, allowing for comparing between the spectral photoresponses of each graphene layer. The curves from the top to the bottom in the panel have decreasing wavelengths. For wavelengths longer than 700 nm, the decay is much slower and eventually the curves show a flat behavior indicating the same normalized photocurrent for all layers. The slower decay is indicative of the increase in absorption depth for increasing wavelength. At 900 nm, all four graphene layers are showing maximum normalized photocurrent, which matches with the exciton resonance peak of the QDs at 920 nm. Close to the exciton resonance wavelength, the absorption is higher due to exciton generation, leading to more photocarriers that results in higher photocurrent. Beyond λ˜1200 nm the response of all the layers decays as light in this range cannot excite photocarriers in the PbS QDs.

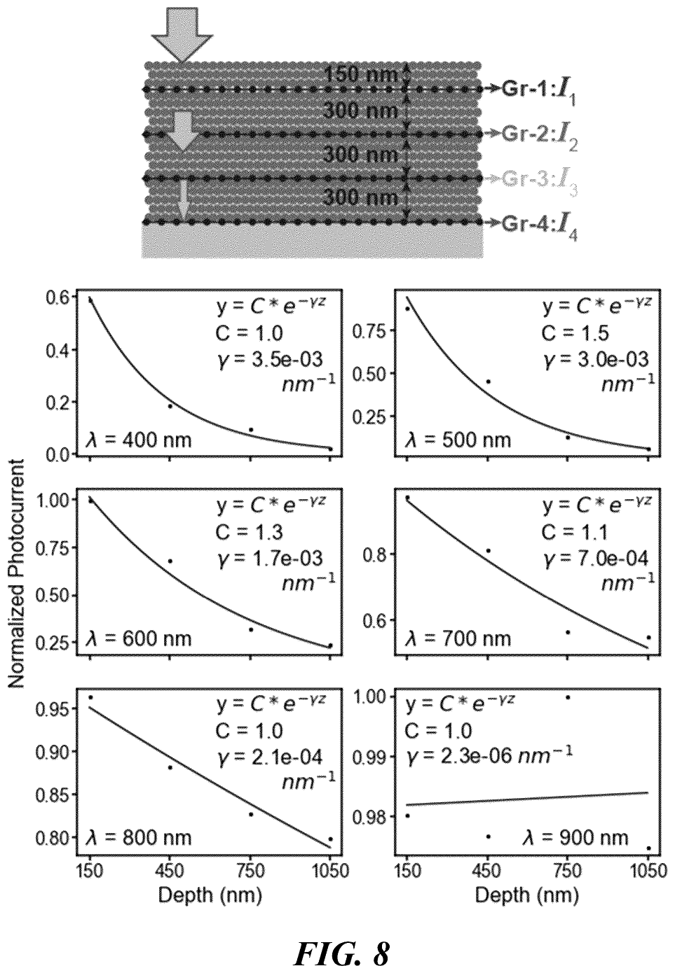

The curves in panel (e) of FIG. 4 are fitted to an exponential, ˜exp (−γz) (see FIG. 8 showing photocurrent depth coefficient fittings) to calculate the decay coefficient for the normalized photoresponse, which may be referred to as the “Photocurrent Depth Coefficient (γ)”. It allows characterization of the wavelength response of the Single Bandgap device, by combining the photocurrents of all graphene layers into one number for each wavelength. These coefficients are plotted in panel (f) of FIG. 4. Shorter wavelengths have higher coefficients, while longer wavelengths have lower, close to zero, coefficients, following a similar trend as the light absorption coefficient (α(λ)). It should be noted that these two coefficients are not the same. While the absorption coefficient (α(λ)) is a measure of light absorption penetration depth that depends essentially on the QDs, the photocurrent depth coefficient is a measure of photocurrent response as function of depth, therefore it involves not only the QDs, but also the electrical conduction mechanisms, especially the charge transfer between Gr and QDs. This penetration depth coefficient is not a figure of merit to evaluate the performance, but it allows to characterize the photoresponse as a function of depth for different wavelengths which is critical to identify the spectral components from an incoming light source. From the photocurrent depth coefficient, it is possible to estimate the wavelength of an incident light source.

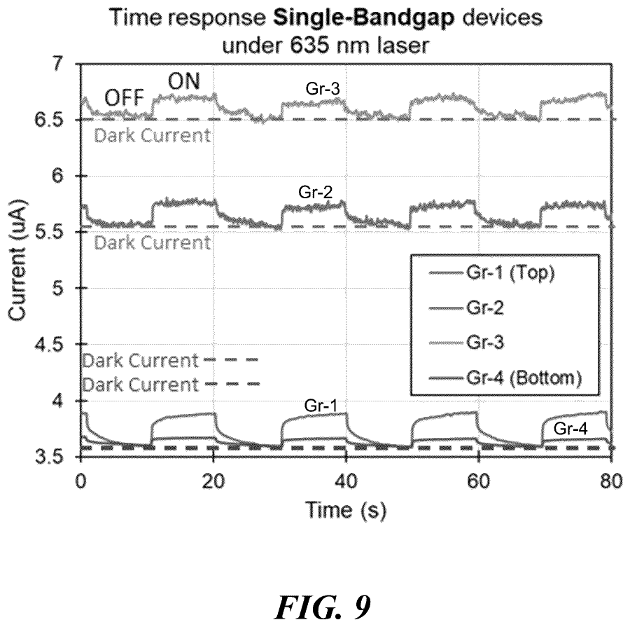

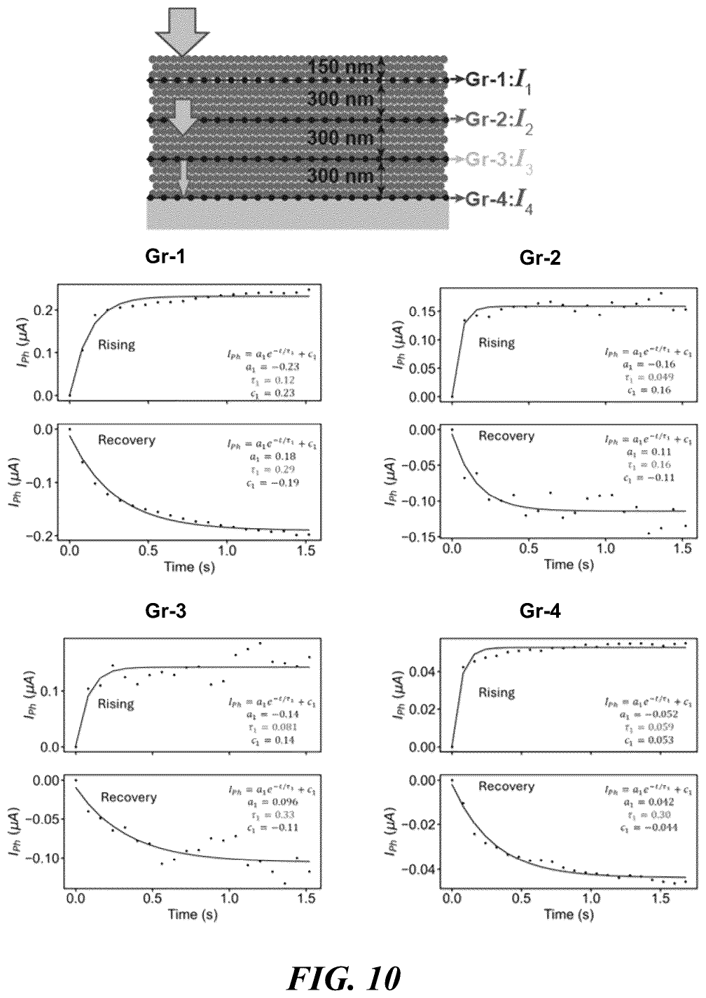

FIG. 9 shows time responses for the single-bandgap device as illustrated in FIG. 4. The time response of the single-bandgap devices under λ˜635 nm is shown in panel (a) of FIG. 9 (see time fittings in FIG. 10). The rising response times from top to bottom (Gr-1 to Gr-4) are 120, 49, 81, and 59 ms, for an average of 77 ms. The recovery times have two components with fast components showing recovery times of 290, 160, 330, and 300 ms, for an average of 270 ms that account for about 50% of the decay, and slower recovery times with a second slower component in the order of approximately 2 s. The slower recovery times are usually associated with traps in the QDs that extend the lifetime of minority electrons carriers responsible for the photogain effect, resulting in slower recovery times. This has been observed in similar hybrid Gr-PbS QD photodetectors by others. Others reported response times of 10 ms but recovery times with slow component of 2 s, and both response and recovery times longer than 2 s also associated with surface traps. An exemplary route to increase the speed of the devices is to use top-bottom configurations whose response now requires current through the QD film that are faster because their response is determined by the much shorter lifetime of majority carriers. Others show that top-bottom contacts can reach much faster responses in the ˜1 μs-20 ns range. Using top-bottom configurations, others have demonstrated also fast responses of 24-59 ms using top-bottom configurations, and fast responses of 10 ms using a top-ITO active layer on the Gr/QD interface. The dashed curves represent the dark currents measured at the respective graphene layers at various depths. All four layers exhibit stable dark current baselines with minimal drift.

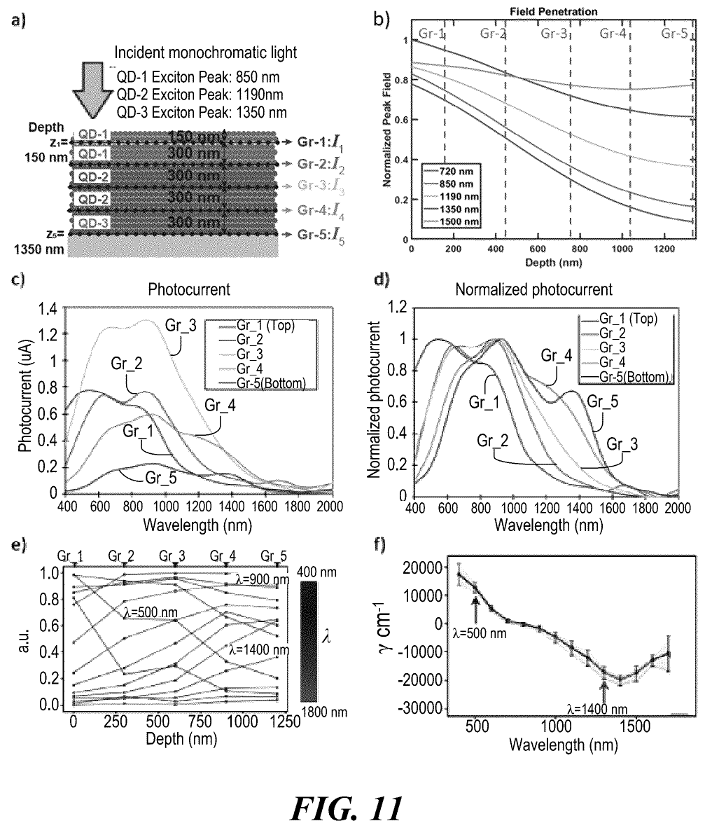

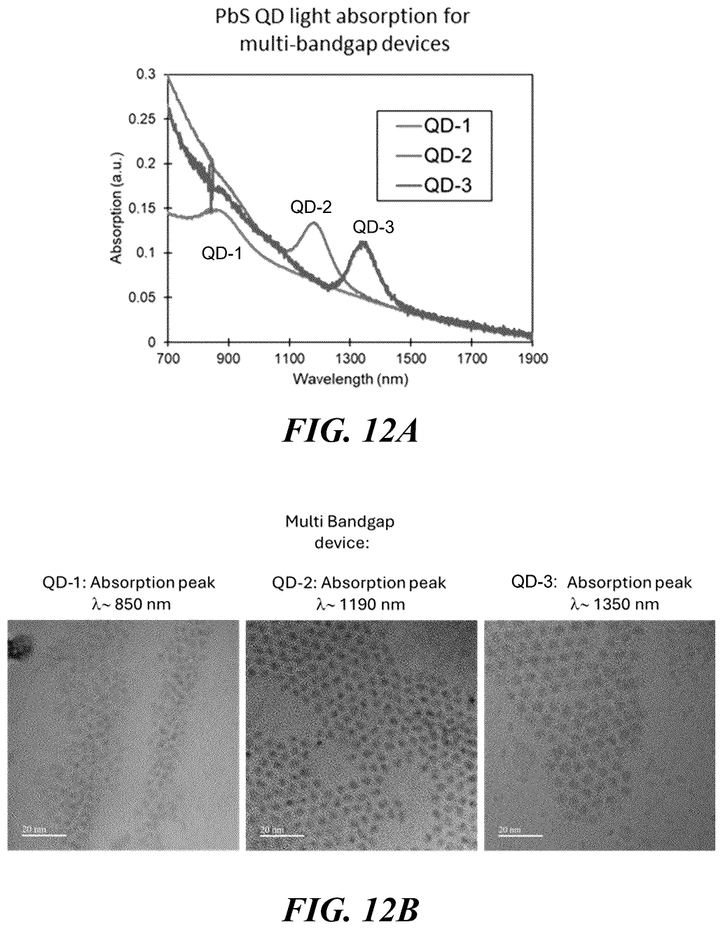

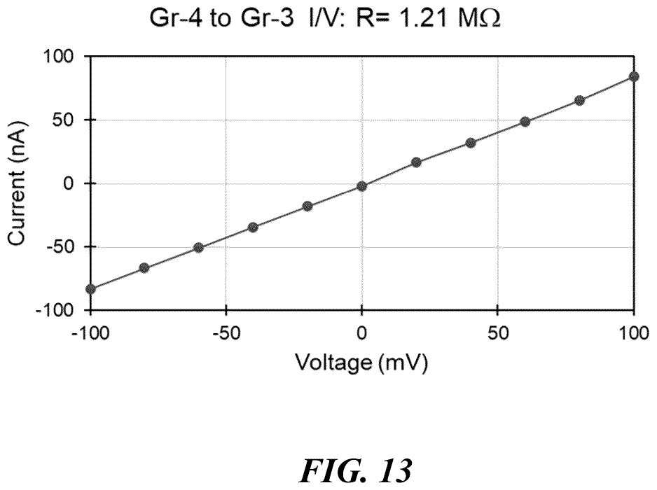

Multi-bandgap devices using different types of QDs (e.g., 3 PbS QDs of different sizes) may expand the spectral range and enhance the spectral separation for different graphene layers, as shown in panel (a) of FIG. 11. Such a device may include small size QDs with large bandgap to absorb short wavelengths, and large size QDs with smaller bandgaps at the bottom (closer to the substrate) to absorb longer wavelengths. The UV/Vis absorption spectra of the PbS QDs are shown in FIG. 12A, showing excitonic peaks at λ˜850 nm for QD-1, λ˜1190 nm for QD-2, and λ˜1350 nm for QD-3. FIG. 12B show TEM images of the QDs. The devices have 5 layers of PbS QDs intercalated with 5 graphene layers with the following sequence from top to bottom: QD-1/Gr/QD-1/Gr/QD-2/Gr/QD-2/Gr/QD-3/Gr. The first QD layer has a thickness of ˜150 nm and the subsequent layers of 300 nm. Therefore, the graphene layers are located at depths of z˜150, 450, 750, 1050 and 1350 nm. The I/V current between Gr-4 and Gr-3 through the bottom QD layer is shown in FIG. 13 showing a resistance of 1.21 MΩ.

Similar to the case of the single-bandgap device in FIG. 4, thicknesses are chosen to ensure effective charge transport and collection from the PbS QDs to Gr. The resistance for each graphene was measured with a 2401 Keithley applying a voltage of 40 mV giving R=5.1, 2.5, 1.8, 3.0 and 4.08 kΩ for Gr-1 to Gr-5, respectively. The field penetration as a function of wavelength through the stack is shown in panel (b) of FIG. 11, showing the expected deeper penetration depths for longer wavelengths. The photocurrent for each graphene layer in the multi-bandgap device is shown in pane (c) of FIG. 11. This device achieves a broader spectral response, covering a range of λ:400-1500 nm, which is broader than λ:400-1200 nm for the single-bandgap device as in FIG. 4. However, the photoresponse from each graphene layer follows a different trend. The highest photocurrent is obtained by the Gr-3 (middle) layer. Then, Gr-1 (Top) and Gr-2 show similar photocurrent levels but lower than Gr-3, and then the lowest responses are obtained from Gr-4 and then from Gr-5 (Bottom). This is different from the single-bandgap device in panel (c) of FIG. 4 in which the photocurrent decreases from top to bottom graphene layers. The simulations for light penetration from panel (b) of FIG. 11 do not show any significant concentration of the field or light absorption at the Gr-3 position (depth=750 nm), therefore, this enhancement may be due to a more efficient charge collection mechanism between QD-2 type and Gr-3. This may be due to a better charge transfer among the QDs related to better conductivity and mobility for QD-2, or improved charge transfer mechanisms from QD-2 film to Gr due to band alignment, built-in potential and surface state considerations. This indicates that to a detailed study on the efficiency of charge transfer from QDs to Gr as a function of QD size is required. Previously, it has been reported that even with QDs of the same composition such as PbS, the coupling and charge transfer from QDs to Gr changes with QD size. The results in panel (c) of FIG. 11 indicate there may be a strong photocarrier generation and coupling between QD_2 and Gr-3 that results in the strongest photocurrent at Gr-3 despite being at deeper levels than Gr-1 and Gr-2.

A multi-bandgap device may extend the spectral response range and enhance the spectral splitting, compared to a single-bandgap device. To focus on the spectral response, we again used min-max normalization as shown in panel (d) of FIG. 11. This illustrates the difference in spectral response for each Gr layer, clearly showing a shift towards longer wavelengths for deeper graphene layers. This contrasts with the Single-Bandgap devices, in which all Gr layers had the same long wavelength limit response due to all QDs having the same bandgap. In the multi-bandgap case, Gr-1 (Top) has normalized response above 0.6 in the Δλ_{Gr_1}˜300-950 nm range, while the Gr-5 (Bottom) shifts to Δλ_{Gr_5}˜600-1400 nm. The long wavelength limits of their spectral ranges, λ_{Gr_1}˜950 nm and λ_{Gr_5}˜1400 nm, are shifted by about 450 nm, compared to 150 nm for the Single Bandgap device (λ_{Gr_1}˜1150 nm and λ_{Gr_5}˜1300 nm). For the single bandgap device, the redshift from top graphene layer to bottom graphene layer is due to the increase in absorption depth with increasing wavelength. The extra graphene and QD layer of the multi-bandgap device (Gr-5 at a depth of 1350 nm for the multi-bandgap device, compared to Gr-4 at a depth of 1050 nm for the single bandgap device in FIG. 4) may induce an additional redshift, but it appears insufficient to account for large difference in redshift between the two types of devices. Therefore, the larger redshift for the multi-bandgap device may be due mostly to the different bandgaps of QDs used in multi-bandgap device. The smaller bandgap QDs at the bottom of the device may be more responsive to the longer wavelength photons that penetrate to that depth. As the spectral response for the graphene layers follows the absorption spectrum of the QDs, the shifts in spectral photocurrent response from Gr-1 to Gr-5 (450 nm) clearly reflect the shift in exciton peak and absorption spectrum from QD-1 to QD-3 (500 nm).

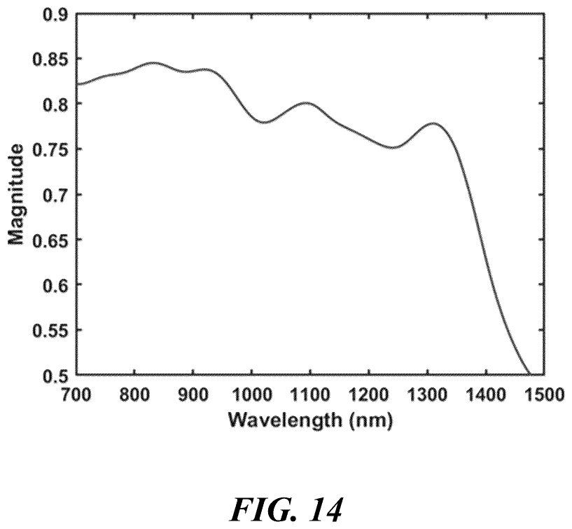

FIG. 14 shows absorption through an entire stack as a function of wavelengths for the multi-bandgap device in FIG. 11, obtained by finite element method (FEM) simulation of light absorption, showing significant absorption up to λ˜1300 nm.

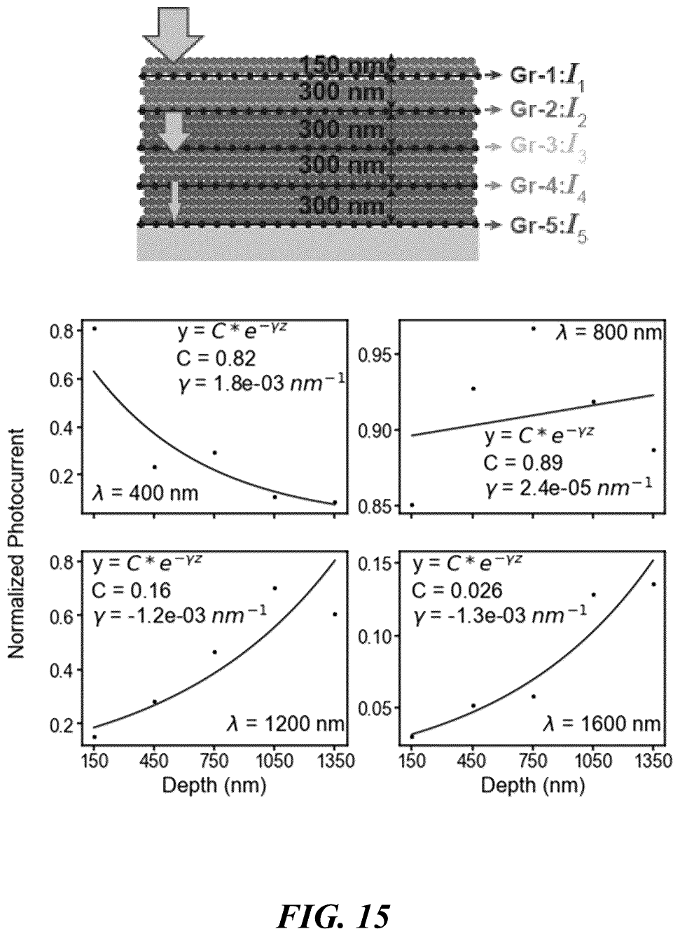

The normalized photocurrent as function of depth, using the depth location of the Gr layers is shown in panel (e) of FIG. 11. This plot clearly shows that for short wavelengths of λ˜400-600 nm (traces that have generally descending trends), the normalized photocurrent decreases from top to bottom graphene layers. Then, for λ˜900 nm the normalized photocurrent appears to be uniform through the different Gr layers. Then, for λ˜1000-1400 nm (traces that have generally ascending trends at a top portion of the panel), the normalized photocurrent clearly increases for deeper layers, which is a direct consequence of the decreasing bandgap profile of the QDs. These wavelengths (low-energy photons) cannot be absorbed by large bandgap QDs on top, but as they reach bottom layers with QDs with lower bandgaps, their absorption increases. Finally, for λ>1400 nm (traces that have generally ascending trends at a bottom portion of the panel, like λ˜1800 nm), even the QD-3 layers cannot absorb photons and the layer becomes practically transparent with zero photoresponse. This behavior can be quantified again by fitting the normalized photocurrent versus depth to an exponential ˜exp (−γz) to characterize the decay with the normalized photocurrent coefficient “γ” as shown in panel (f) of FIG. 11 (see FIG. 15 for fittings). This plot shows that short wavelengths, λ<800 nm, have normal positive coefficients, while longer wavelengths, λ˜800-1400 nm, have negative coefficients. Once the wavelength goes beyond the QD absorption edge (λ>1400 nm) the film becomes transparent, and the coefficients return to zero. Since we have different QDs, “γ” represents an effective device response for the 5Gr/5QD stack rather than a physical property of any of the QD layers. However, it is interesting to observe negative normalized photocurrent coefficients for λ>800 nm that reflect that longer wavelengths are absorbed more efficiently at deeper levels due to our decreasing bandgap profile. These results show that using the multi-bandgap configuration with multiple QDs enables not only to extend the spectral range, but also for easier identification of long wavelengths by a finite negative coefficient ‘γ’, instead of the γ→0 decaying behavior that is more difficult to quantify for the Single-Bandgap case. With QDs of different sizes, the photocurrent depth coefficients of the Multi-Bandgap device can be correlated to each incident wavelength between 400 nm and 1400 nm, enabling wavelength identification and spectral analysis.

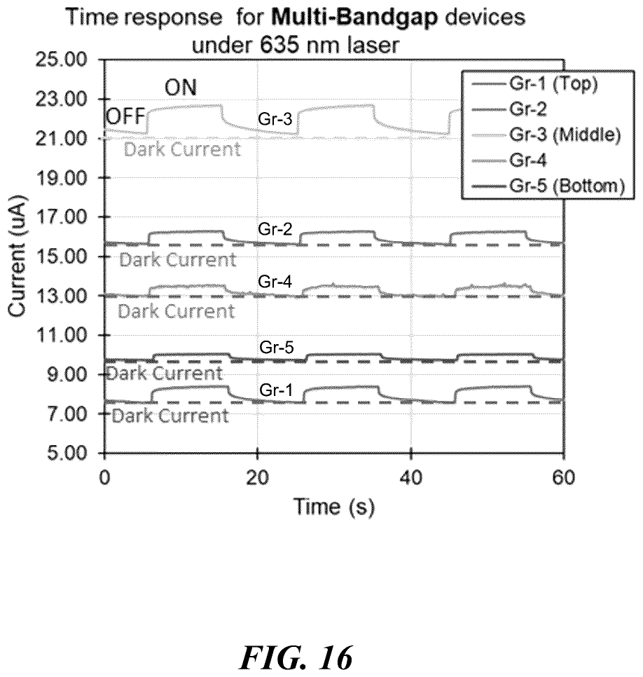

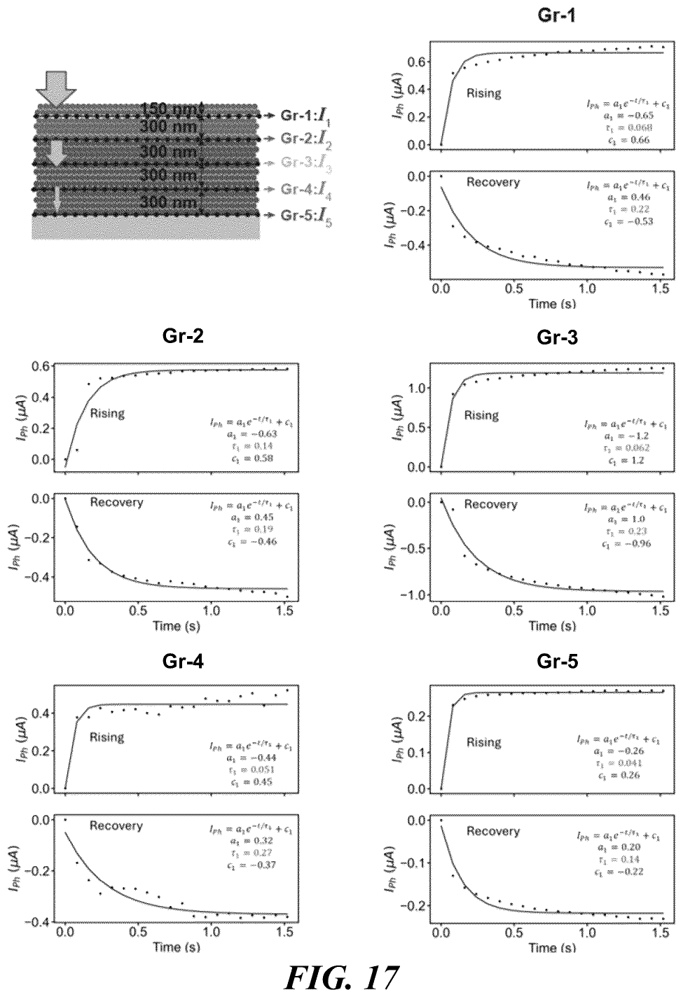

The time responses for the multi-bandgap device are shown in FIG. 16. The rise time for the graphene layers from top (Gr-1) to bottom (Gr-5) are 68, 140, 62, 51, and 41 ms. The average for the five graphene layers is 72 ms. The recovery times from top to bottom are 220, 190, 230, 270 and 140 ms, with an average for the five layers of 210 ms. However, the recovery times also show a slower component of ˜2 seconds associated with surface traps as discussed previously for the Single-Bandgap devices. The dashed curves represent the dark currents measured at the respective graphene layers at various depths. All four layers exhibit stable dark current baselines with minimal drift. The time fittings are shown in FIG. 17.

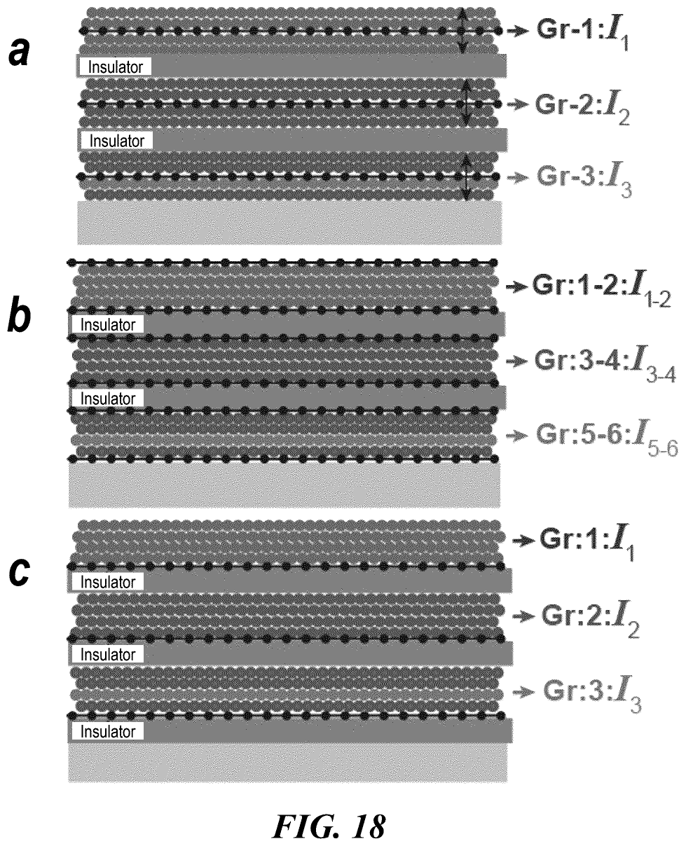

FIG. 18 shows an exemplary multispectral photodetection device according to some embodiments of the present technology. Panel (a) shows a device configuration with insulators (or referred to as insulating layers) positioned between adjacent light-absorbing layers, where each graphene charge-collecting layer (Gr-1, Gr-2, Gr-3) has independent electrical contacts (I₁, I₂, I₃) and is separated by the insulators to reduce electrical coupling between graphene layers. Panel (b) illustrates an alternative configuration where pairs of graphene layers are combined (Gr:1-2, Gr:3-4, Gr:5-6) with shared electrical contacts (I₁₋₂, I₃₋₄, I₅₋₆), also incorporating insulating layers between detection layer groups. Panel (c) demonstrates a third configuration with individual graphene layers (Gr:1, Gr:2, Gr:3) having separate contacts (I₁, I₂, I₃) and insulating layers positioned between each light-absorbing layer to provide electrical isolation.

The incorporation of insulating layers provides opportunities for optimized device design while leveraging materials that are both optically transparent and electrically insulating to preserve light transmission through the device stack while preventing or reducing electrical cross-talk between charge-collecting layers. The insulating layers may include transparent dielectric materials. Examples include hexagonal boron nitride, silicon nitride, silicon oxide, and SU-8 photoresist. These materials can be selected based on one or more selectin criteria including optical transparency, dielectric properties, processing compatibility, and/or electrical isolation characteristics. This device architecture maintains the principle of wavelength-dependent light penetration for multispectral detection while providing enhanced electrical isolation between the charge-collecting layers at different depths. The different configurations (a), (b), and (c) demonstrate various approaches to implementing insulating layers while maintaining independent or grouped electrical measurements from the intercalated graphene and quantum dot structure.

In some embodiments, a multispectral photodetection device (e.g., a single-bandgap or multi-bandgap device as illustrated in FIGS. 1 and 18) includes charge-collecting layers and light-absorbing layers with various geometric relationships. In certain implementations, each of at least one of the plurality of charge-collecting layers and a corresponding electrically connected light-absorbing layer have substantially overlapping footprints. In some implementations, each of at least one of the plurality of charge-collecting layers has a footprint different from (e.g., smaller than) that of its corresponding electrically connected light-absorbing layer. In some implementations, a multispectral photodetection device includes at least a first charge-collecting layer whose footprint substantially overlaps that of its corresponding electrically connected light-absorbing layer and at least a second charge-collecting layer whose footprint is different from (e.g., smaller than) that of its corresponding electrically connected light-absorbing layer, thereby providing design flexibility for improving or optimizing charge collection efficiency and device performance across different detection layers within the same device. The term “footprint” may refer to the two-dimensional area or outline that a layer (e.g., a light-absorbing layer, a charge-collecting layer) occupies when projected onto the substrate surface, representing the perimeter boundary of the layer as viewed perpendicular to the substrate plane.

### Exemplary Processes for Making a Multispectral Photodetection Device

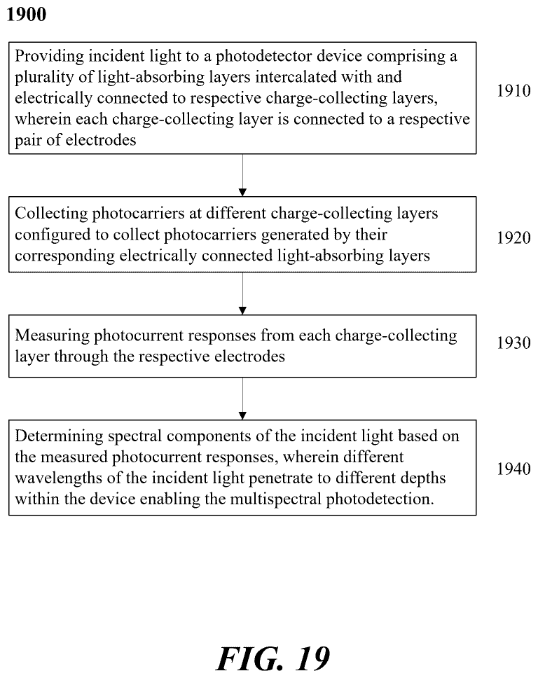

FIG. 19 shows the flowchart of a process 1900 of multispectral photodetection according to some embodiments of the present technology. The device may include various configurations as described in the present document, including single-bandgap or multi-bandgap configurations. The process 1900 includes, at 1910, providing incident light to a photodetector device comprising a plurality of light-absorbing layers intercalated with and electrically connected to respective charge-collecting layers. The process 1900 includes, at 1920, collecting photocarriers at different charge-collecting layers configured to collect photocarriers generated by their corresponding electrically connected light-absorbing layers. The process 1900 includes, at 1930, measuring photocurrent responses from each charge-collecting layer through the respective electrodes. The process 1900 includes, at 1940, determining spectral components of the incident light based on the measured photocurrent responses. Different wavelengths of the incident light may penetrate to different depths within the device enabling the multispectral detection. The process 1900 may additionally include determining a photocurrent depth coefficient for different wavelengths based on the photocurrent responses to characterize wavelength-dependent light penetration through the device. This process 1900 enables multispectral photodetection across wavelengths spanning from visible to short-wave infrared without external beam splitting or spectral filtering components, utilizing the principle that different wavelengths penetrate to different depths within the intercalated device structure.

### Exemplary Processes for Making a Multispectral Photodetection Device

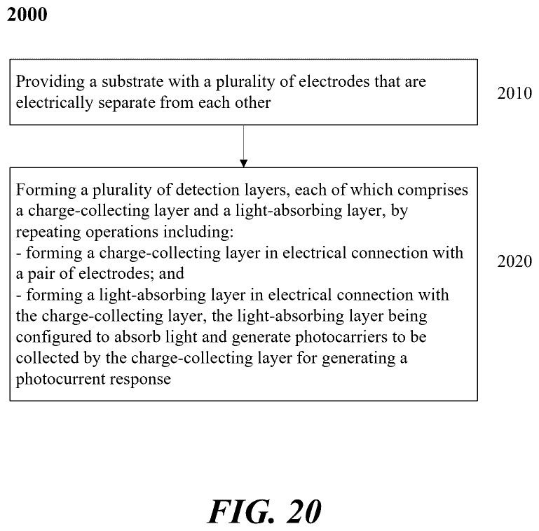

FIG. 20 shows the flowchart of a process 2000 of manufacturing a multispectral photodetection device according to some embodiments of the present technology. The process 2000 includes, at 2010, providing a substrate with a plurality of electrodes that are electrically separate from each other. In some embodiments, the electrodes may comprise a multilayer structure (e.g., chromium/gold/copper) with protective layers that can be removed after patterning corresponding light-absorbing layers to expose underlying material (e.g. gold) to serve as electrical contacts or electrodes.

The process 2000 includes, at 2020, forming a plurality of detection layers. A detection layer includes a charge-collecting layer and a light-absorbing layer. The operation 2020 includes repeating operations that include forming a charge-collecting layer in electrical connection with a pair of electrodes and forming a light-absorbing layer in electrical connection with the charge-collecting layer.

The forming of a charge-collecting layer may include depositing a layer of an electrically conductive material using techniques including sputtering, atomic layer deposition (ALD), solution processing, chemical vapor deposition (CVD), or exfoliation (e.g., mechanical and wet transfer techniques), followed by patterning the layer into a geometry with connecting arms for electrical connection with the pair of electrodes. Suitable materials for charge-collecting layers need to be both optically transparent and electrically conductive to enable light transmission through the device while providing effective charge collection from photocarriers generated in adjacent light-absorbing layers. These materials need to maintain high optical transparency to preserve wavelength-dependent light penetration throughout the intercalated stack. Simultaneously, they have sufficient electrical conductivity to efficiently collect and transport photocarriers to the electrode contacts. The charge-collecting layers may include transparent conductive materials such as, e.g., graphene, two-dimensional molybdenum disulfide (MoS₂), and indium gallium zinc oxide (IGZO), etc. These materials can be selected based on their optical transparency, electrical conductivity, charge transfer properties, and processing compatibility with the quantum dot layers and fabrication requirements.

The forming of a light-absorbing layer may comprise spin coating quantum dots and performing ligand exchange (such as replacing oleic acid ligands with TBAI) to facilitate charge transport between quantum dots. The operations may also include patterning the light-absorbing layer (such as by plasma etching using H₂/CH₄/Ar plasma) to expose electrodes for electrical connection with subsequently formed charge-collecting layers. Suitable materials for light-absorbing layers need to efficiently absorb incident light and generate photocarriers while maintaining compatibility with the intercalated device architecture. These materials need to strong optical absorption across the desired spectral range to maximize photocarrier generation. The light-absorbing layers may include quantum dot materials such as lead sulfide (PbS) quantum dots, which can be synthesized with varying sizes to achieve different bandgaps and absorption wavelengths. Other suitable quantum dot materials include lead selenide (PbSe), cadmium selenide (CdSe), indium arsenide (InAs), and mercury telluride (HgTe) quantum dots, which provide access to different spectral ranges from visible to infrared wavelengths. These materials can be selected based on their absorption characteristics, bandgap tunability, solution processability, and charge transport properties. The quantum dots may be functionalized with appropriate ligands and can undergo ligand exchange processes to optimize charge transport and compatibility with the charge-collecting layers in the intercalated structure.

The light-absorbing layer is configured to absorb light and generate photocarriers. The charge-collecting layer is configured to collect and transport at least a portion of the photocarriers generated in the electrically connected light-absorbing layer to the electrode contacts. The resulting device is configured such that different wavelengths of incident light penetrate to different depths within the device, enabling multispectral detection based on photocurrent responses from the plurality of charge-collecting layers measured through the respective electrodes.

The process 2000 can accommodate various device configurations including quantum dots with different bandgaps arranged with larger bandgaps closer to the light incident surface (multi-bandgap configuration), quantum dots with substantially identical bandgaps (single-bandgap configuration), and light-absorbing layers with different thicknesses for optimized performance.

### Discussion

The technology presented herein show fabrication achievements towards spectral analysis using only the wavelength dependent penetration depth by means of intercalated graphene collectors with independent electrodes into a bandgap tunable light absorption film made of QDs. A single-bandgap device (panel (a) of FIG. 1) allows to probe the absorption depth of light in a QD film, which potentially can be used to identify the wavelength of monochromatic or narrow band sources. A multi-bandgap device (panel (b) of FIG. 1) may achieve an expanded spectral response by incorporating materials with different band gaps and/or achieve negative photocurrent, which may facilitate the identification of longer wavelengths. The multispectral device as disclosed herein may be configured to separate spectral responses from various graphene layer. From the fabrication perspective, QDs layers thicker than the penetration depth may be included to work as filters to reduce the response of graphene layers located at deeper levels. Incorporating insulating layers to prevent possible electrical cross-talking between different graphene layers (FIG. 18) can also reduce the overlap in spectral response. Data science and machine learning techniques may be involved to enhanced spectral analysis and device optimization through comprehensive data collection and sophisticated regression analysis algorithms. The observed variations in coupling and photocurrent levels in multi-bandgap devices provide valuable insights for surface chemistry optimization, enabling precise control and enhancement of photocarrier transfer mechanisms between quantum dots and graphene layers. Continued developments in graphene transfer techniques and quantum dot solution processing present opportunities for improved device reliability, enhanced fabrication throughput, and scalable manufacturing processes suitable for commercial applications.

Compared to previous literature reports, the present technology offers advantages. The intercalated devices as disclosed herein offer a multi channel band response, showing, e.g., up to 5 graphene channels. Integrating different materials with different bandgaps may allow the device to reach both deeper UV ranges and longer IR (MWIR) ranges. The vertical stacking avoids to couple lateral resolution with spectral range. Compared with conventional multispectral detectors, the Gr/QD photodetectors exemplified herein offer large spectral range.

### Conclusions

In conclusion, the technology of intercalated light-absorbing and charge-collecting layers (e.g., QDs and Gr monolayers), in combination with independent electrodes for charge-collecting layers at different depths, allowing to probe the light absorption as a function of depth by means of the photocurrent of the graphene layers. Devices with a single type of QDs (single-bandgap) show that short wavelengths are mainly absorbed at the top with rapid photocurrent decays through the stack, while deeper graphene layers respond only to the longer wavelengths that have deeper penetration depths to reach the bottom of the stack. This device behavior is quantified by a parameter referred to as the photocurrent depth coefficient ‘γ’ that is obtained by fitting the normalized photocurrent to a decaying exponential function exp (−γz), showing large coefficients for short wavelengths and γ→0 for long wavelengths. An improvement is the integration of QDs with different sizes, decreasing the bandgap of the QDs from top to bottom. This enables not only to extend the spectral response, but also to achieve finite negative photocurrent depth coefficients for long wavelengths which can facilitate the identification of infrared components. These ‘γ’ coefficients encode the device response and offer a new alternative for wavelength discrimination and identification for spectral analysis. This technology does not require any long-path dispersive or interferometer components, resulting in a compact (˜1 μm) thin film with potential spectral analysis capabilities. The fabrication process may integrate semiconductor foundries for large scale manufacturing.

The technology provides opportunities for comprehensive characterization through advanced analytical techniques such as time-resolved photoluminescence (PL), UV photoelectron spectroscopy, and transient photovoltage measurements to elucidate band-alignment and charge transfer mechanisms between graphene and quantum dots, thereby enabling optimization of charge transfer processes that contribute to device performance alongside optical absorption. The intercalated architecture offers potential for enhanced long-term stability through systematic investigation of environmental factors including humidity conditions, implementation of passivation layers, and optimization of graphene intercalation parameters. The technology enables continued advancement in design and fabrication methodologies to achieve improved spectral resolution, while the multi-layer detection approach provides rich datasets suitable for sophisticated data analysis methods and machine learning algorithms that can extract comprehensive spectral information from the collective response of the graphene charge-collecting layers.

The following examples are illustrative of several embodiments of the present technology:

Solution 1. A multispectral photodetector device, comprising: a plurality of light-absorbing layers configured to absorb light and generate photocarriers; a plurality of charge-collecting layers intercalated with and electrically connected to respective light-absorbing layers, each charge-collecting layer being configured to collect photocarriers generated by a corresponding electrically connected light-absorbing layer; and a plurality of electrodes electrically connected to respective charge-collecting layers at different depths within the device, wherein the device is configured such that different wavelengths of incident light penetrate to different depths within the device, enabling multispectral detection based on photocurrent responses from the plurality of charge-collecting layers measured through the respective electrodes.

Solution 2. The multispectral photodetector device of any one or more of solution 1 or any other solutions disclosed herein, comprising a substrate supporting the plurality of light-absorbing layers and the plurality of charge-collecting layers.

Solution 3. The multispectral photodetector device of any one or more of solution 2 or any other solutions disclosed herein, wherein the substrate comprises at least one of a silicon layer or a silicon oxide layer.

Solution 4. The multispectral photodetector device of any one or more of solution 1 or any other solutions disclosed herein, wherein the plurality of light-absorbing layers and the plurality of charge-collecting layers are arranged in an alternating sequence.

Solution 5. The multispectral photodetector device of any one or more of solution 1 or any other solutions disclosed herein, wherein the plurality of light-absorbing layers comprise quantum dot layers.

Solution 6. The multispectral photodetector device of any one or more of solution 5 or any other solutions disclosed herein, wherein the quantum dot layers comprise PbS quantum dots.

Solution 7. The multispectral photodetector device of any one or more of solution 18 or any other solutions disclosed herein, wherein the plurality of charge-collecting layers comprise at least one material selected from the group consisting of: graphene, indium gallium zinc oxide (IGZO), or 2-D molybdenum disulfide.

Solution 8. The multispectral photodetector device of any one or more of solution 1 or any other solutions disclosed herein, wherein each of at least one of the plurality of charge-collecting layers is sufficiently transparent to permit at least a portion of incident light to pass through to an adjacent charge-absorbing layer.

Solution 9. The multispectral photodetector device of any one or more of solution 1 or any other solutions disclosed herein, wherein each of at least one of the plurality of charge-collecting layers comprises a graphene monolayer.

Solution 10. The multispectral photodetector device of any one or more of solution 1 or any other solutions disclosed herein, wherein the plurality of light-absorbing layers have substantially identical bandgap, forming a single-bandgap device configuration.

Solution 11. The multispectral photodetector device of any one or more of solution 10 or any other solutions disclosed herein, wherein each of the plurality of light-absorbing layers comprises quantum dots having an exciton absorption peak within a range from 300 nm to 3000 nm.

Solution 12. The multispectral photodetector device of any one or more of solution 1 or any other solutions disclosed herein, wherein the plurality of light-absorbing layers comprise layers with different bandgaps arranged such that a first light-absorbing layer having a first bandgap is positioned closer to a light incident surface of the device than a second layer having a second bandgap that is smaller than the first bandgap, forming a multi-bandgap device configuration.

Solution 13. The multispectral photodetector device of any one or more of solution 12 or any other solutions disclosed herein, wherein each of the plurality of light-absorbing layers comprises quantum dots having an exciton absorption peak at a wavelength within a range from 300 nm to 3000 nm.

Solution 14. The multispectral photodetector device of any one or more of solution 1 or any other solutions disclosed herein, wherein the device is configured to provide multispectral detection across wavelengths spanning from visible to short-wave infrared.

Solution 15. The multispectral photodetector device of any one or more of solution 1 or any other solutions disclosed herein, wherein each of at least one of the plurality of charge-collecting layers is patterned to form a structure with connecting arms to be electrically connected to corresponding electrodes.

Solution 16. The multispectral photodetector device of any one or more of solution 1 or any other solutions disclosed herein, comprising an insulating layer positioned between adjacent light-absorbing layers to reduce electrical coupling between charge-collecting layers.

Solution 17. The multispectral photodetector device of any one or more of solution 16 or any other solutions disclosed herein, wherein the insulating layer comprises at least one material selected from the group consisting of: hexagonal boron nitride, silicon nitride, silicon oxide, and SU-8 photoresist.

Solution 18. The multispectral photodetector device of any one or more of solution 1 or any other solutions disclosed herein, wherein each of the plurality of light-absorbing layers has a thickness in a range from 50 nm to 500 nm.

Solution 19. The multispectral photodetector device of any one or more of solution 1 or any other solutions disclosed herein, wherein at least two of the plurality of light-absorbing layers have different thicknesses.

Solution 20. The multispectral photodetector device of any one or more of solution 1 or any other solutions disclosed herein, wherein the device is configured to characterize wavelength-dependent light penetration through the device.

Solution 21. The multispectral photodetector device of any one or more of solution 1 or any other solutions disclosed herein, wherein each of at least one of the plurality of electrodes comprise a gold electrode with a chromium adhesion layer.

Solution 22. The multispectral photodetector device of any one or more of solution 1 or any other solutions disclosed herein, wherein the device comprises at least two light-absorbing layers and at least two charge-collecting layers.

Solution 23. The multispectral photodetector device of any one or more of solution 1 or any other solutions disclosed herein, wherein each of at least one of the plurality of charge-collecting layers and a corresponding electrically connected light-absorbing layer have substantially overlapping footprints.

Solution 24. A method of multispectral photodetection, comprising: providing incident light to a photodetector device comprising a plurality of light-absorbing layers intercalated with and electrically connected to respective charge-collecting layers, wherein each charge-collecting layer is connected to a respective pair of electrodes; collecting photocarriers at different charge-collecting layers configured to collect photocarriers generated by corresponding electrically connected light-absorbing layers; measuring photocurrent responses from each charge-collecting layer through the respective electrodes; and determining spectral components of the incident light based on the measured photocurrent responses, wherein different wavelengths of the incident light penetrate to different depths within the device enabling the multispectral photodetection.

Solution 25. The method of any one or more of solution 24 or any other solutions disclosed herein, comprising determining a photocurrent depth coefficient for different wavelengths based on the photocurrent responses to characterize wavelength-dependent light penetration through the device.

Solution 26. A method of manufacturing a multispectral photodetector device, comprising: providing a substrate with a plurality of electrodes that are electrically separate from each other; and forming a plurality of detection layers, each of which comprises a charge-collecting layer and a light-absorbing layer, by repeating operations including: forming a charge-collecting layer in electrical connection with a pair of electrodes; and forming a light-absorbing layer in electrical connection with the charge-collecting layer, the light-absorbing layer being configured to absorb light and generate photocarriers to be collected by the charge-collecting layer for generating a photocurrent response, wherein the device is configured such that different wavelengths of incident light penetrate to different depths within the device, enabling multispectral detection based on the photocurrent responses from the plurality of charge-collecting layers measured through the respective electrodes.

Solution 27. The method of any one or more of solution 26 or any other solutions disclosed herein, wherein forming a charge-collecting layer comprises: depositing a layer of an electrically conductive material; and forming the charge-collecting layer by patterning the layer of the electrically conductive material into a geometry with connecting arms for electrical connection with the pair of electrodes.

Solution 28. The method of any one or more of solution 27 or any other solutions disclosed herein, wherein the electrically conductive material comprises at least one material selected from the group consisting of: graphene, Indium Gallium Zinc Oxide (IGZO), or 2-D Molybdenum Disulfide.

Solution 29. The method of any one or more of solution 27 or any other solutions disclosed herein, wherein the depositing the layer of the electrically conductive material comprises applying at least one technique of sputtering, atomic layer deposition (ALD), solution processing, chemical vapor deposition (CVD), or exfoliation.

Solution 30. The method of any one or more of solution 26 or any other solutions disclosed herein, wherein forming a light-absorbing layer comprises: spin coating quantum dots; and performing ligand exchange to facilitate charge transport between quantum dots.

Solution 31. The method of any one or more of solution 30 or any other solutions disclosed herein, wherein the ligand exchange comprises replacing oleic acid ligands with tetrabutylammonium iodide (TBAI).

Solution 32. The method of any one or more of solution 26 or any other solutions disclosed herein, wherein the operations for forming one of the plurality of detection layers comprise patterning the light-absorbing layer of the detection layer to expose at least some of the electrodes on the substrate for electrical connection with at least one subsequently formed charge-collecting layer.

Solution 33. The method of any one or more of solution 32 or any other solutions disclosed herein, wherein patterning the light-absorbing layer comprises plasma etching using H₂/CH₄/Ar plasma.

Solution 34. The method of any one or more of solution 26 or any other solutions disclosed herein, wherein each of at least one of the plurality of electrodes comprises chromium/gold/copper multilayer structures with a protective copper layer.

Solution 35. The method of any one or more of solution 34 or any other solutions disclosed herein, comprising removing the protective copper layer after patterning a corresponding light-absorbing layer to expose underlying gold contact.

Solution 36. The method of any one or more of solution 26 or any other solutions disclosed herein, wherein at least two of the plurality of light-absorbing layers comprise quantum dots with different bandgaps arranged with larger bandgaps closer to a light incident surface of the device.

Solution 37. The method of any one or more of solution 26 or any other solutions disclosed herein, wherein at least two of the plurality of light-absorbing layers comprise quantum dots with substantially identical bandgaps.

Solution 38. The method of any one or more of solution 26 or any other solutions disclosed herein, wherein at least two of the plurality of light-absorbing layers have different thicknesses.

Solution 39. A device for detecting wavelengths of light, comprising: a substrate; a first set of layers comprising quantum dots, the first set of layers configured to generate photocarriers from light incident upon the device such that a photocurrent is produced within the device; a second set of layers comprising graphene, the second set of layers configured to collect the photocurrent by absorbing the photocarriers generated by the first set of layers; and electrodes in contact with respective layers of the second set of layers at different depths within the device, wherein the first set of layers and the second set of layers are arranged on the substrate in a configuration that enables wavelengths of the light to be detected based on a decay rate of the photocurrent collected by respective layers of the second set of layers.

Solution 40. The device of any one or more of solution 39 or any other solutions disclosed herein, wherein the configuration is an alternating sequence of layers comprising respective layers of the first set of layers and respective layers of the second set of layers.

Solution 41. The device of any one or more of solution 39 or any other solutions disclosed herein, wherein the first set of layers comprises PbS quantum dots.

Solution 42. The device of any one or more of solution 39 or any other solutions disclosed herein, wherein the first set of layers comprises quantum dots of varying sizes.

Solution 43. The device of any one or more of solution 39 or any other solutions disclosed herein, wherein the first set of layers comprises quantum dots that are substantially similar in size.

Solution 44. The device of any one or more of solution 39 or any other solutions disclosed herein, wherein the second set of layers comprises graphene monolayers.

Solution 45. The device of any one or more of solution 39 or any other solutions disclosed herein, wherein the configuration includes a dielectric layer positioned between each layer of the first set of layers.

Solution 46. The device of any one or more of solution 39 or any other solutions disclosed herein, wherein each of the first set of layers has a different band gap.

Solution 47. The device of any one or more of solution 39 or any other solutions disclosed herein, wherein the decay rate of the photocurrent changes with depth inside the device.

Solution 48. The device of any one or more of solution 39 or any other solutions disclosed herein, wherein the electrodes comprise gold.

Solution 49. A system for multispectral photodetection, including any one or more of solution 1 or 39, or other solutions disclosed herein.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A multispectral photodetector device, comprising:
a plurality of light-absorbing layers configured to absorb light and generate photocarriers;
a plurality of charge-collecting layers intercalated with and electrically connected to respective light-absorbing layers, each charge-collecting layer being configured to collect photocarriers generated by a corresponding electrically connected light-absorbing layer; and
a plurality of electrodes electrically connected to respective charge-collecting layers at different depths within the device,
wherein the device is configured such that different wavelengths of incident light penetrate to different depths within the device, enabling multispectral detection based on photocurrent responses from the plurality of charge-collecting layers measured through the respective electrodes.

2. The multispectral photodetector device of claim 1, comprising a substrate supporting the plurality of light-absorbing layers and the plurality of charge-collecting layers.

3. The multispectral photodetector device of claim 2, wherein the substrate comprises at least one of a silicon layer or a silicon oxide layer.

4. The multispectral photodetector device of claim 1, wherein the plurality of light-absorbing layers comprise quantum dot layers.

5. The multispectral photodetector device of claim 4, wherein the quantum dot layers comprise PbS quantum dots.

6. The multispectral photodetector device of claim 1, wherein the plurality of charge-collecting layers comprise at least one material selected from the group consisting of: graphene, indium gallium zinc oxide (IGZO), or 2-D molybdenum disulfide.

7. The multispectral photodetector device of claim 1, wherein each of at least one of the plurality of charge-collecting layers comprises a graphene monolayer.

8. The multispectral photodetector device of claim 1, wherein the plurality of light-absorbing layers have substantially identical bandgap, forming a single-bandgap device configuration.

9. The multispectral photodetector device of claim 1, wherein the plurality of light-absorbing layers comprise layers with different bandgaps arranged such that a first light-absorbing layer having a first bandgap is positioned closer to a light incident surface of the device than a second layer having a second bandgap that is smaller than the first bandgap, forming a multi-bandgap device configuration.

10. The multispectral photodetector device of claim 1, wherein the device is configured to provide multispectral detection across wavelengths spanning from visible to short-wave infrared.

11. The multispectral photodetector device of claim 1, wherein each of at least one of the plurality of charge-collecting layers is patterned to form a structure with connecting arms to be electrically connected to corresponding electrodes.

12. The multispectral photodetector device of claim 1, comprising an insulating layer positioned between adjacent light-absorbing layers to reduce electrical coupling between charge-collecting layers.

13. The multispectral photodetector device of claim 12, wherein the insulating layer comprises at least one material selected from the group consisting of: hexagonal boron nitride, silicon nitride, silicon oxide, and SU-8 photoresist.

14. The multispectral photodetector device of claim 1, wherein each of the plurality of light-absorbing layers has a thickness in a range from 50 nm to 500 nm.

15. The multispectral photodetector device of claim 1, wherein at least two of the plurality of light-absorbing layers have different thicknesses.

16. The multispectral photodetector device of claim 1, wherein each of at least one of the plurality of electrodes comprise a gold electrode with a chromium adhesion layer.

17. A method of multispectral photodetection, comprising:
providing incident light to a photodetector device comprising a plurality of light-absorbing layers intercalated with and electrically connected to respective charge-collecting layers, wherein each charge-collecting layer is connected to a respective pair of electrodes;
collecting photocarriers at different charge-collecting layers configured to collect photocarriers generated by corresponding electrically connected light-absorbing layers;
measuring photocurrent responses from each charge-collecting layer through the respective electrodes; and
determining spectral components of the incident light based on the measured photocurrent responses, wherein different wavelengths of the incident light penetrate to different depths within the device enabling the multispectral photodetection.

18. The method of claim 17, comprising determining a photocurrent depth coefficient for different wavelengths based on the photocurrent responses to characterize wavelength-dependent light penetration through the device.

19. A method of manufacturing a multispectral photodetector device, comprising:
providing a substrate with a plurality of electrodes that are electrically separate from each other; and
forming a plurality of detection layers, each of which comprises a charge-collecting layer and a light-absorbing layer, by repeating operations including: forming a charge-collecting layer in electrical connection with a pair of electrodes; and forming a light-absorbing layer in electrical connection with the charge-collecting layer, the light-absorbing layer being configured to absorb light and generate photocarriers to be collected by the charge-collecting layer for generating a photocurrent response,
wherein the device is configured such that different wavelengths of incident light penetrate to different depths within the device, enabling multispectral detection based on the photocurrent responses from the plurality of charge-collecting layers measured through the respective electrodes.

20. The method of claim 19, wherein forming a charge-collecting layer comprises:
depositing a layer of an electrically conductive material; and
forming the charge-collecting layer by patterning the layer of the electrically conductive material into a geometry with connecting arms for electrical connection with the pair of electrodes.
